(19) United States
(12) Patent Application Publication
(10) Pub. No.: US 2010/0173472 A1
(43) Pub. Date: Jul. 8, 2010

(54) METHOD FOR MANUFACTURING SOI SUBSTRATE AND METHOD FOR MANUFACTURING SEMICONDUCTOR DEVICE

(75) Inventor: Yoji NAGANO, Atsugi (JP)

Correspondence Address: Robinson Intellectual Property Law Office, P.C., 3975 Fair Ridge Drive, Suite 20 North, Fairfax, VA, 22033, US

(73) Assignee: SEMICONDUCTOR ENERGY LABORATORY CO., LTD., Kanagawa-ken (JP)

(21) Appl. No.: 12/648,631

(22) Filed: Dec. 29, 2009

(30) Foreign Application Priority Data
Jan. 5, 2009 (JP) 2009-000239

(51) Int. Cl. H01L 21/762

(52) U.S. Cl. 438/458; 257/E21.568

(57) ABSTRACT

A method for manufacturing an SOI substrate and a method for manufacturing a semiconductor device, in each of which peeling of a single crystal semiconductor layer from an end portion due to laser irradiation is suppressed, are provided. A fragile region is formed in a single crystal semiconductor substrate by irradiating the single crystal semiconductor substrate with an accelerated ion, the single crystal semiconductor substrate is bonded to a base substrate with an insulating layer interposed therebetween, a single crystal semiconductor layer is formed over the base substrate with the insulating layer interposed therebetween by splitting the single crystal semiconductor substrate at the fragile region, an end portion of the single crystal semiconductor layer is removed, and a surface of the single crystal semiconductor layer whose end portion has been removed is irradiated with a laser beam.

### BACKGROUND OF THE INVENTION

1. Field of the Invention

The present invention to be disclosed in this specification relates to a method for manufacturing an SOI (silicon on insulator) substrate where a semiconductor layer is provided over an insulating surface, and a method for manufacturing a semiconductor device including an SOI substrate.

2. Description of the Related Art

In recent years, integrated circuits including an SOI substrate where a thin single crystal semiconductor layer is formed on an insulating surface, instead of a bulk silicon wafer, have been developed. The use of an SOI substrate can reduce parasitic capacitance between a drain of a transistor and a substrate; thus, SOI substrates are attracting attention for their ability to improve performance of semiconductor integrated circuits.

Smart Cut (registered trademark) method is known as one of methods for manufacturing an SOI substrate (for example, see Patent Document 1). An outline of a method for manufacturing an SOI substrate by Smart Cut method is described below. First, hydrogen ions are implanted into a silicon wafer by an ion implantation method, so that a microbubble layer is formed at a predetermined depth from a surface of the silicon wafer. Next, the silicon wafer into which hydrogen ions have been implanted is bonded to another silicon wafer with a silicon oxide film interposed therebetween. Then, thermal treatment is performed, whereby the microbubble layer serves as a cleavage plane and part of the silicon wafer into which hydrogen ions have been implanted is split along the microbubble layer to become a thin film shape. Accordingly, a single crystal silicon film can be formed over the other bonded silicon wafer. Smart Cut (registered trademark) method is sometimes referred to as a hydrogen ion implantation separation method.

A method in which a single crystal silicon layer is formed over a base substrate made of glass by using Smart Cut method as described above has been proposed (for example, see Patent Document 2). Glass substrates can easily have larger sizes and are less expensive than silicon wafers; thus, glass substrates are mainly used in manufacturing liquid crystal display devices and the like. By using such a glass substrate as a base substrate, a large-sized inexpensive SOI substrate can be manufactured.

Further, Patent Document 2 discloses a method in which a single crystal silicon layer is irradiated with a laser beam in order to improve the crystal quality of the single crystal silicon layer.

### [References]

[Patent Document 1] Japanese Published Patent Application No. H05-211128

### [Patent Document 2] Japanese Published Patent Application No. 2005-252244

### SUMMARY OF THE INVENTION

As a method for re-single-crystallizing a single crystal semiconductor layer, there is heat treatment such as heat treatment in a heating furnace or laser irradiation. If the heat treatment is performed in a heating furnace at temperatures over the strain point of the base substrate, the base substrate changes in shape due to warp, shrink, or the like. Therefore, in the case of using a glass substrate as the base substrate, the upper temperature limit of the heat treatment is restricted in accordance with the strain point of glass.

On the other hand, the heat treatment by laser irradiation can instantaneously increase the temperature of a sample to heat the sample selectively. Even in the case of using the base substrate formed using glass having low heat resistance, the irradiation of the single crystal semiconductor layer with a laser beam can perform heat treatment on the single crystal semiconductor layer. By irradiating the single crystal semiconductor layer with a laser beam for melting and re-single-crystallizing the single crystal semiconductor layer, the crystallinity thereof can be recovered.

However, the irradiation of the single crystal semiconductor layer with a laser beam causes the single crystal semiconductor layer to change in stress; as a result, film strip (peeling) occurs at an end of the single crystal semiconductor layer.

In view of the above problems, it is an object to provide a method for manufacturing an SOI substrate, by which film strip at an end of a single crystal semiconductor layer due to laser irradiation is suppressed. It is another object to provide a method for manufacturing a semiconductor device including an SOI substrate, by which film strip at an end of a single crystal semiconductor layer due to laser irradiation is suppressed.

In a method for manufacturing an SOI substrate where a single crystal semiconductor layer is provided over an insulating surface, an end portion of the single crystal semiconductor layer is removed before a surface of the single crystal semiconductor layer is irradiated with a laser beam.

An embodiment of the present invention to be disclosed in this specification includes the steps of forming a fragile region in a single crystal semiconductor substrate by irradiating the single crystal semiconductor substrate with an accelerated ion; bonding the single crystal semiconductor substrate to a base substrate with an insulating layer interposed therebetween; forming a single crystal semiconductor layer over the base substrate with the insulating layer interposed therebetween, by splitting the single crystal semiconductor substrate at the fragile region; removing an end portion of the single crystal semiconductor layer; and irradiating with a laser beam a surface of the single crystal semiconductor layer whose end portion has been removed.

In the above structure, it is preferable to remove an end portion of the insulating layer after the removal of the end portion of the single crystal semiconductor layer and before the irradiation with the laser beam.

In the above structure, the insulating layer is preferably formed as a single layer or a stack of layers, which includes a silicon oxide film, a silicon oxynitride film, a silicon nitride film, or a silicon nitride oxide film.

An embodiment of the present invention to be disclosed in this specification includes the steps of forming an oxide film over a surface of a single crystal semiconductor substrate; forming a fragile region in the single crystal semiconductor substrate by irradiating the single crystal semiconductor substrate with an accelerated ion through the oxide film; bonding the single crystal semiconductor substrate to a base substrate with the oxide film and a nitrogen-containing layer interposed therebetween; forming a single crystal semiconductor layer over the base substrate with the oxide film and the nitrogen-containing layer interposed therebetween, by splitting the single crystal semiconductor substrate at the fragile region; removing an end portion of the single crystal semiconductor layer, and irradiating with a laser beam a surface of the single crystal semiconductor layer whose end portion has been removed.

In the above structure, it is preferable to remove an end portion of the oxide film and an end portion of the nitrogen-containing layer after the removal of the end portion of the single crystal semiconductor layer and before the irradiation with the laser beam.

In the above structure, the oxide film is preferably formed by performing thermal treatment on the single crystal semiconductor substrate in an oxidative atmosphere to which halogen is added.

In the above structure, a silicon nitride film or a silicon nitride oxide film is preferably formed as the nitrogen-containing layer.

In the above structure, the surface of the single crystal semiconductor layer whose end portion has been removed is preferably planarized by the irradiation with the laser beam.

In the above structure, the crystallinity of a superficial portion of the single crystal semiconductor layer whose end portion has been removed is preferably recovered by the irradiation with the laser beam.

In this specification, the term “single crystal” means a crystal solid in which, when a certain crystal axis is considered, that crystal axis is oriented in the same direction in any portion of a sample and there is no crystal grain boundaries between crystals. Note that in this specification, the scope of “single crystal” includes a crystal solid which has uniform crystal axis direction and which has no grain boundaries as described above even though it includes a crystal defect or a dangling bond.

Moreover, in this specification, “re-single-crystallization” of a single crystal semiconductor layer means that a semiconductor layer having a single crystal structure comes to have a single crystal structure again after the structure becomes a state which is different from the former single crystal structure (e.g., a liquid phase state). It can also be said that “re-single-crystallization” of a single crystal semiconductor layer means that a single crystal semiconductor layer is crystallized again to become single crystal, so that a single crystal semiconductor layer is formed.

The term “semiconductor device” in this specification refers to devices that can operate by utilizing semiconductor characteristics, and electro-optical devices, semiconductor circuits, and electronic appliances are included in the category of the semiconductor device.

In addition, in this specification, the category of “display device” includes a light-emitting device and a liquid crystal display device. A light-emitting device includes a light-emitting element, and a liquid crystal display device includes a liquid crystal element. The category of a light-emitting element includes an element whose luminance is controlled by current or voltage, and specifically includes an inorganic electroluminescent (EL) element, an organic EL element, and the like.

In a method for manufacturing an SOI substrate where a single crystal semiconductor layer is provided over an insulating surface, when an end of the single crystal semiconductor layer is removed before a surface of the single crystal semiconductor layer is irradiated with a laser beam, film strip at the end of the single crystal semiconductor layer due to the laser irradiation can be suppressed.

### BRIEF DESCRIPTION OF THE DRAWINGS

FIGS. 1A to 1F are cross-sectional views illustrating an example of a method for manufacturing an SOI substrate.

FIGS. 2A to 2H are cross-sectional views illustrating an example of a method for manufacturing an SOI substrate.

FIGS. 3A to 3C are plan views illustrating an example of a method for manufacturing an SOI substrate.

FIGS. 4A to 4D are cross-sectional views illustrating an example of a method for manufacturing a thin film transistor.

FIGS. 5A to 5C are cross-sectional views illustrating an example of a method for manufacturing a thin film transistor.

FIG. 6 is a block diagram illustrating an example of a structure of a microprocessor.

FIG. 7 is a block diagram illustrating an example of a structure of an RFCPU.

FIGS. 8A and 8B illustrate an example of a liquid crystal display device.

FIGS. 9A and 9B illustrate an example of an electroluminescent display device.

FIGS. 10A to 10C illustrate an example of a cellular phone.

FIGS. 11A to 11D are optical micrographs of end faces of SOI substrates.

FIGS. 12A to 12D are optical micrographs of end faces of SOI substrates.

### DETAILED DESCRIPTION OF THE INVENTION

Embodiments are described in detail with reference to the drawings. However, it is easily understood by those skilled in the art that the modes and details herein disclosed can be modified in a variety of ways without departing from the scope and the spirit of the present invention. Therefore, the present invention is not construed as being limited to the description of Embodiments below. In the structures to be given below, the same portions or portions having similar functions are denoted by the same reference numerals in different drawings, and explanation thereof will not be repeated.

### Embodiment 1

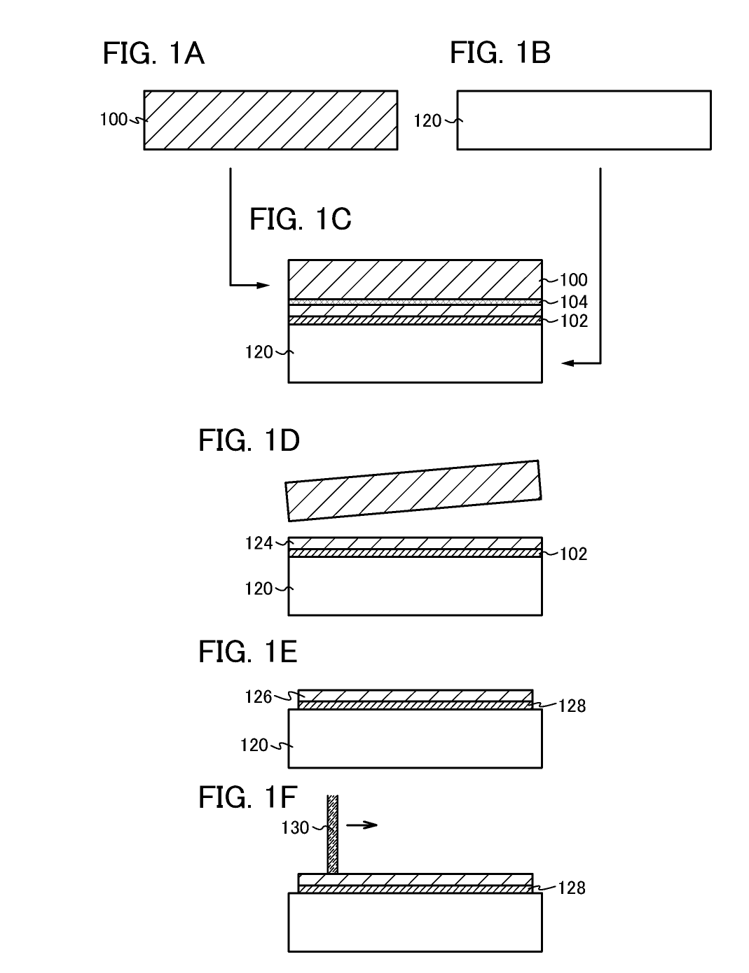

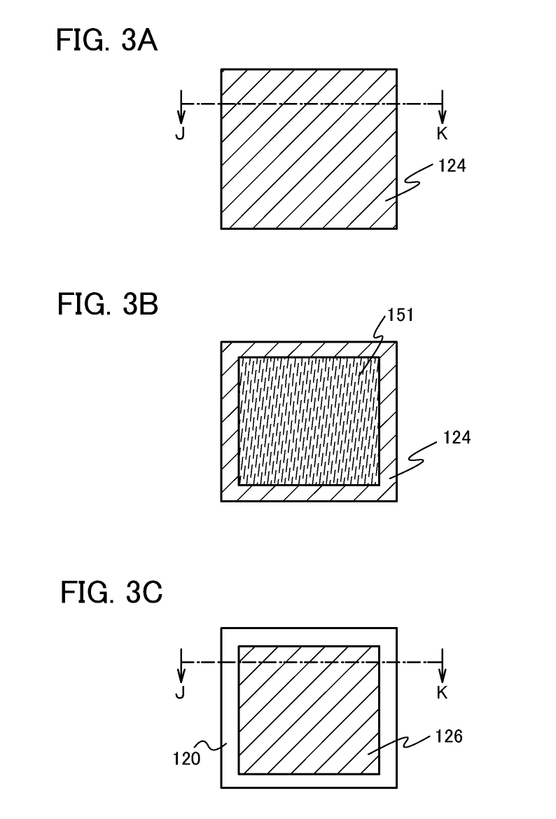

In Embodiment 1, an example of a method for manufacturing an SOI substrate is described with reference to drawings. Specifically, Embodiment 1 describes a method for forming a single crystal semiconductor layer by Smart Cut (registered trademark) method over a base substrate with an insulating layer interposed therebetween and recovering the crystallinity of the single crystal semiconductor layer. FIGS. 1A to 1F are cross-sectional views illustrating an example of a method for manufacturing an SOI substrate, and FIGS. 3A to 3C are plan views of the SOI substrate.

First, a single crystal semiconductor substrate 100 and a base substrate 120 are prepared (see FIGS. 1A and 1B).

As the single crystal semiconductor substrate 100, for example, a single crystal semiconductor substrate including a Group 14 element, such as a single crystal silicon substrate, a single crystal germanium substrate, or a single crystal silicon germanium substrate, can be used. Alternatively, a compound semiconductor substrate including gallium arsenide, indium phosphide, or the like can be used. Commercial silicon substrate are typically circular in shape with diameters of 5 inches (approximately 125 mm), 6 inches (approximately 150 mm), 8 inches (approximately 200 mm), 12 inches (approximately 300 mm), and 16 inches (approximately 400 mm). Note that the shape of the single crystal semiconductor substrate 100 is not limited to a circular shape, and a single crystal semiconductor substrate processed into, for example, a rectangular shape or the like can also be used.

As the base substrate 120, a substrate including an insulator can be used. Specific examples thereof include a variety of glass substrates used in the electronics industry, such as substrates of aluminosilicate glass, aluminoborosilicate glass, and barium borosilicate glass; a quartz substrate; a ceramic substrate; and a sapphire substrate. Further, a single crystal semiconductor substrate such as a single crystal silicon substrate may be used as the base substrate 120. In Embodiment 1, a glass substrate is used as the base substrate 120. When a glass substrate, which can have a large area and is inexpensive, is used as the base substrate 120, the cost can be reduced.

Next, a fragile region 104 with a damaged crystal structure is formed at a predetermined depth from a surface of the single crystal semiconductor substrate 100. Then, the single crystal semiconductor substrate 100 and the base substrate 120 are bonded to each other with an insulating layer 102 interposed therebetween (see FIG. 1C).

The fragile region 104 can be formed by irradiating the single crystal semiconductor substrate 100 with accelerated ions of hydrogen or the like.

The insulating layer 102 can be formed as a single layer or a stack of layers, which includes an insulating layer such as a silicon oxide film, a silicon oxynitride film, a silicon nitride film, or a silicon nitride oxide film. These films can be formed by a thermal oxidation method, a CVD method, a sputtering method, or the like.

In this specification, silicon oxynitride contains more oxygen than nitrogen and, in the case where measurements are performed by rutherford backscattering spectrometry (RBS) and hydrogen forward scattering (HFS), preferably contains oxygen, nitrogen, silicon, and hydrogen at concentrations ranging from 50 at. % to 70 at. %, 0.5 at. % to 15 at. %, 25 at. % to 35 at. %, and 0.1 at. % to 10 at. %, respectively. Further, silicon nitride oxide contains more nitrogen than oxygen and, in the case where measurements are performed using RBS and HFS, preferably contains oxygen, nitrogen, silicon, and hydrogen at concentrations ranging from 5 at. % to 30 at. %, 20 at. % to 55 at. %, 25 at. % to 35 at. %, and 10 at. % to 30 at. %, respectively. Note that percentages of nitrogen, oxygen, silicon, and hydrogen fall within the ranges given above, where the total number of atoms contained in silicon oxynitride or silicon nitride oxide is defined as 100 at. %.

Next, thermal treatment is performed to split the single crystal semiconductor substrate 100 at the fragile region 104, whereby a single crystal semiconductor layer 124 is provided over the base substrate 120 with the insulating layer 102 interposed therebetween (see FIG. 1D and FIG. 3A). FIG. 1D is a cross sectional view taken along line J-K in FIG. 3A.

Due to temperature rise in the thermal treatment, the element added by the ion irradiation is separated out into microvoids which are formed in the fragile region 104, and the internal pressure of the microvoids is increased. By the pressure increase, the microvoids in the fragile region 104 are changed in volume and a crack is generated in the fragile region 104. As a result, the single crystal semiconductor substrate 100 is split along the fragile region 104. Since the insulating layer 102 is bonded to the base substrate 120, the single crystal semiconductor layer 124 which is separated from the single crystal semiconductor substrate 100 is provided over the base substrate 120. Further, the temperature in this thermal treatment is set so as not to exceed the strain point of the base substrate 120.

For this thermal treatment, a heating furnace such as a diffusion furnace or a resistance heating furnace, a rapid thermal annealing (RTA) apparatus, a microwave heating apparatus, or the like can be used. For example, in the case of using an RTA apparatus, the thermal treatment can be performed at a heating temperature of greater than or equal to 550° C. and less than or equal to 730° C., for a processing time of greater than or equal to 0.5 minutes and less than or equal to 60 minutes.

Next, an end portion of the single crystal semiconductor layer 124 and an end portion of the insulating layer 102 are removed by, for example, a photolithography technique and an etching technique.

First, a resist mask 151 with a desired shape is formed over the single crystal semiconductor layer 124. In Embodiment 1, in order to remove the end portion of the single crystal semiconductor layer 124 which has an uneven end face (edge portion), the resist mask 151 is formed so as to have a slightly smaller size than the single crystal semiconductor layer 124 (see FIG. 3B). The resist mask can be easily formed using a wafer edge light-exposure apparatus.

Next, the end portion of the single crystal semiconductor layer 124 is removed using the resist mask 151, whereby a single crystal semiconductor layer 126 is formed. The removal of the end portion of the single crystal semiconductor layer 124 is performed by, for example, etching.

As the etching, dry etching or wet etching can be performed. Preferably, the end portion of the single crystal semiconductor layer 124 is removed by dry etching using the resist mask 151, whereby the single crystal semiconductor layer 126 is formed so as to have a planar end face and not to have a space between the single crystal semiconductor layer 126 and the insulating layer 102 at an end portion of the single crystal semiconductor layer 126 after performing dry etching. As an example, FIG. 3B illustrates the single crystal semiconductor layer 126 which has a rectangular shape with each side having a linear cross section by the removal of the peripheral portion.

Due to the step of splitting the single crystal semiconductor substrate 100 for the provision of the single crystal semiconductor layer 124, the end portion of the single crystal semiconductor layer 124 is destroyed, so that the end face (edge portion) becomes uneven because part of the single crystal semiconductor substrate 100 remains on the split plane of the single crystal semiconductor layer 124 or part of the single crystal semiconductor layer 124 is peeled off at the end portion of the single crystal semiconductor substrate 100. As a result, at the end portion of the single crystal semiconductor layer 124, a space is formed between a bottom surface of the single crystal semiconductor layer 124 and a top surface of the insulating layer 102. Alternatively, due to the step of splitting the single crystal semiconductor substrate 100, the adhesion between the single crystal semiconductor layer 124 and the insulating layer 102 is decreased at the end portion of the single crystal semiconductor layer 124.

In a later step of irradiating this single crystal semiconductor layer 124 with a laser beam, film strip of the single crystal semiconductor layer 124 occurs at the end portion due to the change in stress of the single crystal semiconductor layer 124.

In view of the above, the end portion of the single crystal semiconductor layer 124 is removed before the laser irradiation. By the removal of the end portion, the end face of the end portion can be planarized and the film strip of the single crystal semiconductor layer due to the laser irradiation can be suppressed.

Moreover, in the case where the single crystal semiconductor layer 124 has a mark for product management (this mark is also called an identification number, a wafer identification number, a wafer number, an ID number, or the like), the removal of the end portion of the single crystal semiconductor layer 124 and the removal of a region of the single crystal semiconductor layer where the mark is formed may be performed by the same etching step.

Next, an insulating layer 128 is formed by removing the end portion of the insulating layer 102 with the use of the resist mask 151 formed in the former step. The removal of the end portion of the insulating layer 102 is performed by, for example, etching.

As the etching, dry etching or wet etching may be employed; in any case, the etching is preferably performed so as not to etch the base substrate 120. Preferably, the end portion of the insulating layer 102 is removed by dry etching using the resist mask 151, whereby the insulating layer 128 is formed so as to have a planar end face (edge portion) (see FIG. 1E and FIG. 3C). FIG. 1E is a cross-sectional view taken along line J-K in FIG. 3C.

Note that the step of etching the insulating layer 102 may be omitted in the case where the insulating layer 102 has a planar end face.

After that, the resist mask 151 is removed.

Through the above steps, an SOI substrate where the single crystal semiconductor layer 126 is provided over the base substrate 120 with the insulating layer 128 interposed therebetween can be completed.

Next, a surface of the single crystal semiconductor layer 126 formed over the base substrate 120 is irradiated with a laser beam 130; thus, the surface of the single crystal semiconductor layer 126 is planarized and the crystallinity of a superficial portion of the single crystal semiconductor layer 126 is recovered (re-single-crystallized) (see FIG. 1F).

In general, the crystallinity of the superficial portion of the single crystal semiconductor layer 126 after the split is damaged because of crystal defects and the like formed due to the formation of the fragile region 104, the split at the fragile region 104, and the like. Accordingly, as illustrated in FIG. 1F, the surface of the single crystal semiconductor layer 126 is irradiated with the laser beam 130 to melt at least the superficial portion of the single crystal semiconductor layer 126, whereby the crystallinity can be recovered. Note that the crystallinity of the single crystal semiconductor layer 126 can be known by observation with an optical microscope, Raman shift and a full width at half maximum which are obtained from a Raman spectroscopy spectrum, or the like. In addition, the surface of the single crystal semiconductor layer 126 can be planarized and the crystallinity thereof can be recovered, by melting the superficial portion of the single crystal semiconductor layer 126.

In Embodiment 1, it is preferable that the single crystal semiconductor layer 126 is not melted completely (complete melting) but is melted partially (partial melting) by delivering the laser beam 130 from the surface side of the single crystal semiconductor layer 126 which is exposed by the split. The partial melting refers to melting performed so that the depth of a region of the single crystal semiconductor layer 126 which is melted by the laser beam 130 from the surface of the single crystal semiconductor layer 126 is smaller than the depth of the interface with the insulating layer 102 (the thickness of the melted region of the single crystal semiconductor layer 126 is smaller than the total thickness of the single crystal semiconductor layer 126). In other words, the partial melting refers to melting performed so that an upper part of the single crystal semiconductor layer 126 (including the superficial portion) is melted to become a liquid phase by the laser beam 130 and a lower part thereof is not melted to remain as a solid-phase single crystal semiconductor. Note that the complete melting refers to melting performed so that the single crystal semiconductor layer 126 is melted to become a liquid phase and the liquid phase reaches the interface with the insulating layer 102.

By the partial melting of the single crystal semiconductor layer 126, crystals in the portion melted by the irradiation with the laser beam 130 grow in accordance with a plane direction of the non-melted part of the single crystal semiconductor layer; therefore, re-single-crystallization can be performed with the plane direction aligned as compared with the case of complete melting. Further, when the single crystal semiconductor layer 126 is partially melted, entry of oxygen, nitrogen, and the like from the insulating layer 128 can be suppressed.

Further, the irradiation with the laser beam 130 may be performed in a reduced-pressure atmosphere in Embodiment 1.

As a laser which can be used in Embodiment 1, a laser having an emission wavelength in the range of the ultraviolet to visible light region is selected. In addition, the wavelength of the laser beam 130 is a wavelength which is absorbed by the single crystal semiconductor layer 126. The wavelength can be determined in consideration of the skin depth of the laser beam, and the like. For example, the wavelength can be 250 nm or more and 700 nm or less.

As the laser, a pulsed laser or a continuous wave laser (a CW laser) can be used. As a pulsed laser, a pulsed laser with a repetition rate of less than 10 MHz and a pulse width of 10 ns or more and 500 ns or less is preferably employed. A typical pulsed laser is an excimer laser that emits a laser beam having a wavelength of 400 nm or less. As the excimer laser, a XeCl excimer laser with a repetition rate of 10 Hz to 300 Hz, a pulse width of 25 ns, and a wavelength of 308 nm can be used, for example. In addition, in the scanning with a pulsed laser beam, one shot and the next shot may be partially overlapped with each other for irradiation. By partially overlapping one shot with the next shot in the laser irradiation, refining of single crystals is partially performed repeatedly, whereby a single crystal semiconductor layer having excellent characteristics can be obtained.

Further, the range of the energy density of the laser beam for partially melting the single crystal semiconductor layer 126 is set such that the single crystal semiconductor layer 126 is not completely melted, in consideration of the wavelength of the laser beam, the skin depth thereof, the thickness of the single crystal semiconductor layer 126, and the like. For example, in the case where the thickness of the single crystal semiconductor layer 126 is large, the energy necessary for completely melting the single crystal semiconductor layer 126 is also large, and thus the range of the energy density of the laser beam can be wide. When the thickness of the single crystal semiconductor layer 126 is small, the energy necessary for completely melting the single crystal semiconductor layer 126 is also small, and thus the energy density of the laser beam is preferably set to be small.

In accordance with the method described in Embodiment 1, the film strip of the single crystal semiconductor layer at the end portion due to the laser irradiation can be suppressed.

Note that the structure described in Embodiment 1 can be implemented as appropriate in combination with any of the structures described in the Embodiments of this specification.

### Embodiment 2

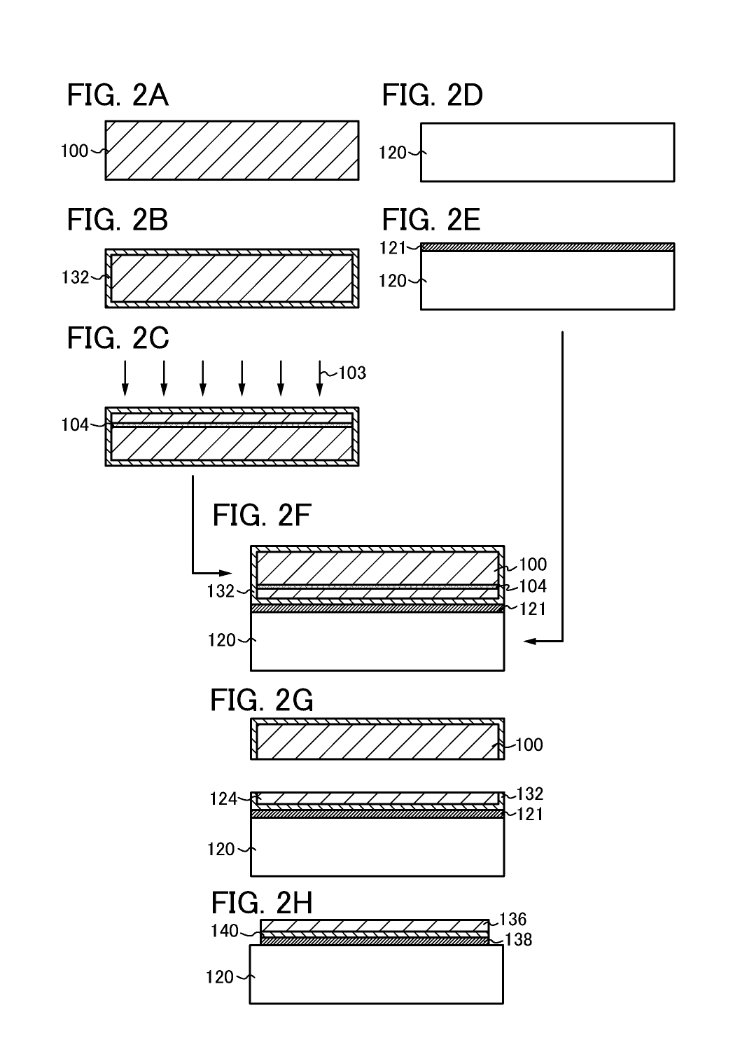

An example of bonding the single crystal semiconductor substrate 100 and the base substrate 120 to each other in the method for manufacturing the SOI substrate described in Embodiment 1 is described in detail with reference to FIGS. 2A to 2H.

First, the single crystal semiconductor substrate 100 is prepared (see FIG. 2A).

It is preferable that a surface of the single crystal semiconductor substrate 100 is cleaned in advance as appropriate with a sulfuric acid/hydrogen peroxide mixture (SPM), an ammonium hydroxide/hydrogen peroxide mixture (APM), a hydrochloric acid/hydrogen peroxide mixture (HPM), dilute hydrofluoric acid (DHF), or the like in order to remove contamination. Dilute hydrofluoric acid and ozone water may be discharged alternately for cleaning.

Next, an oxide film 132 is formed over the surface of the single crystal semiconductor substrate 100 (see FIG. 2B).

As the oxide film 132, a single layer or a stack of layers can be formed using a silicon oxide film, a silicon oxynitride film, or the like. These films can be formed by a thermal oxidation method, a CVD method, a sputtering method, or the like. In addition, when a silicon oxide film is formed as the oxide film 132 by a CVD method, a silicon oxide film formed by using organosilane such as tetraethoxysilane (abbreviation: TEOS, chemical formula: Si(OC₂H₅)₄) is preferable in terms of productivity.

In Embodiment 2, the oxide film 132 (here, the silicon oxide film) is formed by performing thermal oxidation treatment on the single crystal semiconductor substrate 100 as illustrated in FIG. 2B. The thermal oxidation treatment is preferably performed in an oxidative atmosphere to which halogen is added because a halogen atom can be added to the oxide film 132.

For example, thermal oxidation treatment of the single crystal semiconductor substrate 100 is performed in an oxidative atmosphere to which chlorine (Cl) is added, whereby the oxide film 132 can be formed by chlorine oxidation. In this case, the oxide film 132 includes a chlorine atom.

The chlorine atom in the oxide film 132 forms a distortion in the oxide film 132. As a result, the moisture absorptance of the oxide film 132 is increased and the diffusion speed is increased. Namely, when moisture exists on a surface of the oxide film 132, the moisture can be rapidly absorbed and diffused in the oxide film 132.

In an example of the thermal oxidation treatment, the thermal oxidation can be performed in an oxidative atmosphere which contains hydrogen chloride (HCl) at a proportion of 0.5 vol. % to 10 vol. % (preferably, 3 vol. %) with respect to oxygen at a temperature of 750° C. to 1150° C., preferably 900° C. to 1100° C. (typically, 1000° C.). The treatment time is 0.1 to 6 hours, preferably 0.5 to 1 hour. The thickness of the oxide film to be formed is set to 10 nm to 1000 nm (preferably, 50 nm to 300 nm), for example, 100 nm The formation of the oxide film 132 in an oxidative atmosphere containing chlorine can increase the withstand voltage and reduce the interface state density between the single crystal semiconductor substrate 100 and the oxide film 132.

In Embodiment 2, the concentration of the chlorine atoms in the oxide film 132 is controlled so as to be in the range of 1×10¹⁷ atoms/cm³ to 1×10²¹ atoms/cm³. The inclusion of the chlorine atom in the oxide film 132 is effective in preventing contamination of the single crystal semiconductor substrate 100 because heavy metal (for example, Fe, Cr, Ni, or Mo) that is an extrinsic impurity is captured in the oxide film 132.

When a halogen atom such as a chlorine atom is contained in the oxide film 132 by chlorine oxidation or the like, an impurity which has an adverse effect on the single crystal semiconductor substrate 100 (for example, a mobile ion such as Na) can be captured by gettering. That is, by the thermal treatment performed after the oxide film 132 is formed, an impurity contained in the single crystal semiconductor substrate 100 is separated out to the oxide film 132 and reacts with halogen to be captured. Thus, the impurity captured is fixed in the oxide film 132, so that contamination of the single crystal semiconductor substrate 100 can be prevented. Moreover, in the case of bonding the base substrate, which is a glass substrate, to the single crystal semiconductor substrate 100, the oxide film 132 can prevent contamination of the single crystal semiconductor substrate because an impurity in glass such as Na is fixed.

In particular, for example, in the case where a semiconductor substrate is not cleaned sufficiently or the case where contaminant of a semiconductor substrate which is reused repeatedly is removed, it is effective that a halogen atom such as a chlorine atom is contained in the oxide film 132 by chlorine oxidation or the like.

Note that the halogen atom contained in the oxide film 132 is not limited to the chlorine atom. A fluorine atom may be contained in the oxide film 132. As a method for performing fluorine oxidation on the surface of the single crystal semiconductor substrate 100, there are a method in which the single crystal semiconductor substrate 100 is soaked in hydrofluoric acid and then subjected to thermal oxidation treatment in an oxidative atmosphere, a method in which thermal oxidation treatment is performed in an oxidative atmosphere to which NF₃ is added, and the like.

Next, the single crystal semiconductor substrate 100 is irradiated with ions 103 having kinetic energy, whereby the fragile region 104 having a damaged crystal structure is formed at a predetermined depth from the surface of the single crystal semiconductor substrate 100 (see FIG. 2C). When the single crystal semiconductor substrate 100 is irradiated with the accelerated ions 103 through the oxide film 132 as illustrated in FIG. 2C, the fragile region 104 can be formed in a region at a predetermined depth from the surface of the single crystal semiconductor substrate 100. The ions 103 are obtained in such a manner that a source gas is excited to produce plasma of the source gas and the ions contained in the plasma are extracted from the plasma by an electric field effect and accelerated.

Alternatively, the fragile region 104 may be formed by the irradiation with the ions 103 while the single crystal semiconductor substrate 100 is cooled. When the irradiation with the ions 103 is performed while the single crystal semiconductor substrate 100 is cooled, the temperature rise of the single crystal semiconductor substrate 100 can be suppressed even in the case where a large area of the single crystal semiconductor substrate 100 is irradiated with the ions at a time. As a result, thermal diffusion of the delivered ions can be suppressed, and broadening of distribution of the added ions in a depth direction can be reduced. Further, by suppression of the temperature rise of the single crystal semiconductor substrate 100, the release of hydrogen which is added into the single crystal semiconductor substrate 100 can be reduced. Accordingly, the time for irradiation with the ions 103 can be shortened and throughput can be improved.

In Embodiment 2, hydrogen is added to the single crystal semiconductor substrate 100 using an ion doping apparatus. A gas containing hydrogen is used as a source gas. As for the ions used for the irradiation, the proportion of H₃⁺ is preferably set high. Specifically, it is preferable that the proportion of H₃⁺ be set 50% or higher (more preferably, 80% or higher) with respect to the total amount of H⁺, H₂⁺, and H₃⁺. By the increase in proportion of H₃⁺, the efficiency of hydrogen addition owing to the ion irradiation can be improved.

In addition, when an ion doping apparatus is used, there is a possibility that a heavy metal is introduced at the same time; however, by performing the ion irradiation through the oxide film 132 including a chlorine atom, the single crystal semiconductor substrate 100 can be prevented from being contaminated by a heavy metal.

Next, the base substrate 120 is prepared (see FIG. 2D).

A surface of the base substrate 120 is preferably cleaned in advance. Specifically, ultrasonic cleaning is performed on the base substrate 120 using a hydrochloric acid/hydrogen peroxide mixture (HPM), a sulfuric acid/hydrogen peroxide mixture (SPM), an ammonium hydroxide/hydrogen peroxide mixture (APM), dilute hydrofluoric acid (DHF), or the like. For example, the surface of the base substrate 120 is preferably cleaned by ultrasonic cleaning with the use of HPM. Through such cleaning treatment, the surface planarity of the base substrate 120 can be improved and abrasive particles left on the surface of the base substrate 120 can be removed, for example.

Next, a nitrogen-containing layer 121 (for example, an insulating film containing nitrogen, such as a silicon nitride film or a silicon nitride oxide film) is formed on the surface of the base substrate 120 (see FIG. 2E).

In Embodiment 2, the nitrogen-containing layer 121 formed in Embodiment 2 will serve as a layer (bonding layer) used for bonding with the oxide film 132 which is provided over the single crystal semiconductor substrate 100. When a single crystal semiconductor layer is provided over the base substrate later, the nitrogen-containing layer 121 also functions as a barrier layer for preventing an impurity such as sodium (Na) contained in the base substrate from diffusing into the single crystal semiconductor layer.

Since the nitrogen-containing layer 121 is used as the bonding layer, the nitrogen-containing layer 121 is preferably formed to have a surface with a predetermined planarity. Specifically, the nitrogen-containing layer 121 is preferably formed to have a surface with an average surface roughness (Rₐ) of 0.5 nm or less and a root-mean-square surface roughness (Rₘₛ) of 0.60 nm or less, more preferably, an average surface roughness of 0.35 nm or less and a root-mean-square surface roughness of 0.45 nm or less. The thickness of the nitrogen-containing layer 121 is set to 10 nm or more and 200 nm or less, preferably 50 nm or more and 100 nm or less. With such a high degree of surface planarity, defective bonding of the single crystal semiconductor layer can be prevented.

Next, the surface of the single crystal semiconductor substrate 100 and the surface of the base substrate 120 are disposed so as to face each other and then the surface of the oxide film 132 and the surface of the nitrogen-containing layer 121 are bonded to each other (see FIG. 2F).

Here, a pressure of approximately 1 N/cm² to 500 N/cm², more preferably approximately 1 N/cm² to 20 N/cm² is applied to a portion of the single crystal semiconductor substrate 100 after the single crystal semiconductor substrate 100 and the base substrate 120 are disposed in close contact with each other with the oxide film 132 and the nitrogen-containing layer 121 interposed therebetween. Bonding between the oxide film 132 and the nitrogen-containing layer 121 begins at the pressed portion and then the spontaneous bonding proceeds throughout the surface. This bonding step is performed by the action of van der Waals force or hydrogen bonding and can be performed at room temperature without any thermal treatment. Therefore, a substrate having a low allowable temperature limit, such as a glass substrate, can be used as the base substrate 120.

Note that, before the single crystal semiconductor substrate 100 and the base substrate 120 are bonded to each other, at least one of the oxide film 132 formed over the single crystal semiconductor substrate 100 and the nitrogen-containing layer 121 formed over the base substrate 120 is preferably subjected to surface treatment.

As the surface treatment, plasma treatment, ozone treatment, megasonic cleaning, or two-fluid cleaning (a method in which functional water such as pure water or hydrogen-containing water is sprayed together with a carrier gas such as nitrogen), or a combination thereof can be performed. In particular, ozone treatment, megasonic cleaning, two-fluid cleaning, or the like is performed after the surface of at least one of the oxide film 132 and the nitrogen-containing layer 121 is subjected to plasma treatment, whereby dust such as an organic substance on the surface of the oxide film 132 and/or the surface of the nitrogen-containing layer 121 can be removed and the surface can be made hydrophilic. As a result, the bonding strength between the oxide film 132 and the nitrogen-containing layer 121 can be increased.

Here, an example of ozone treatment is described. For example, ozone treatment can be performed on a surface of an object by irradiation with ultraviolet (UV) light in an atmosphere containing oxygen. Ozone treatment in which irradiation with ultraviolet light is performed under an atmosphere containing oxygen is also called UV ozone treatment, ultraviolet ozone treatment, or the like. In an atmosphere containing oxygen, irradiation with ultraviolet light having a wavelength of less than 200 nm and ultraviolet light having a wavelength of greater than or equal to 200 nm is performed, whereby ozone can be generated and singlet oxygen can be generated by ozone. When irradiation with ultraviolet light having a wavelength of less than 180 nm is performed, ozone can be generated and singlet oxygen can be generated from ozone.

Examples of reactions which occur by the irradiation with light having a wavelength of less than 200 nm and light having a wavelength of greater than or equal to 200 nm in an atmosphere containing oxygen are described.

O₂+hν(λ₁ nm)→O(³P)+O(³P) (1)

O(³P)+O₂→O₃ (2)

O₃+hν(λ₂ nm)→O(¹D)+O₂ (3)

In the above reaction formula (1), irradiation with light (hν) having a wavelength (λ₁ nm) of less than 200 nm in an atmosphere containing oxygen (O₂) is performed to generate an oxygen atom (O(³P)) in a ground state. Next, in the reaction formula (2), an oxygen atom (O(³P)) in a ground state and oxygen (O₂) react with each other to generate ozone (O₃). Then, in the reaction formula (3), irradiation with light having a wavelength (λ₂ nm) of greater than or equal to 200 nm in an atmosphere containing generated ozone (O₃) is performed to generate singlet oxygen O(¹D) in an excited state. In an atmosphere containing oxygen, irradiation with ultraviolet light having a wavelength of less than 200 nm is performed to generate ozone and irradiation with ultraviolet light having a wavelength of greater than or equal to 200 nm is performed to generate singlet oxygen by decomposing the ozone. The ozone treatment as described above, for example, can be performed by irradiation with light of a low-pressure mercury lamp (λ₁=185 nm, λ₂=254 nm) in an atmosphere containing oxygen.

In addition, examples of reactions which occur by the irradiation with light having a wavelength of less than 180 nm in an atmosphere containing oxygen are described.

O₂+hν(λ₃ nm)→O(¹D)+O(³P) (4)

O(³P)+O₂→O₃ (5)

O₃+hν(λ₃ nm)→O(¹D)+O₂ (6)

In the above reaction formula (4), irradiation with light having a wavelength (λ₃ nm) of less than 180 nm in an atmosphere containing oxygen (O₂) is performed to generate singlet oxygen O(¹D) in an excited state and an oxygen atom (O(³P)) in a ground state. Next, in the reaction formula (5), an oxygen atom (O(³P)) in a ground state and oxygen (O₂) react with each other to generate ozone (O₃). In the reaction formula (6), irradiation with light having a wavelength (λ₃ nm) of less than 180 nm in an atmosphere containing generated ozone (O₃) is performed to generate singlet oxygen in an excited state and oxygen. In an atmosphere containing oxygen, irradiation with ultraviolet light having a wavelength of less than 180 nm is performed to generate ozone and to generate singlet oxygen by decomposing ozone or oxygen. The ozone treatment as described above, for example, can be performed by irradiation with light of a Xe excimer UV lamp (λ₃=172 nm) in an atmosphere containing oxygen.

Chemical bonding of an organic substance attached to a surface of an object is cut by light having a wavelength of less than 200 nm, whereby the organic substance attached to the surface of the object, the organic substance whose chemical bonding, or the like is cut can be removed by oxidative decomposition by ozone or singlet oxygen generated from ozone. By performing the ozone treatment as described above, the hydrophilicity and cleanliness of the surface of the object to be processed can be increased and favorable bonding can be performed.

Ozone is generated by performing irradiation with ultraviolet light in an atmosphere containing oxygen. Ozone is effective in removal of the organic substance attached to the surface of the object. In addition, singlet oxygen is also effective in removal of the organic substance attached to the surface of the object as much as or more than ozone. Ozone and singlet oxygen are examples of oxygen in an active state, and also called active oxygen collectively. As described with the above reaction formulae and the like, since there are reactions where ozone is generated in generating singlet oxygen or singlet oxygen is generated from ozone, here, such reactions including a reaction where singlet oxygen contributes are called ozone treatment for convenience.

Note that, after the oxide film 132 and the nitrogen-containing layer 121 are bonded to each other, thermal treatment is preferably performed in order to increase the bonding strength. This thermal treatment is performed at a temperature where a crack is not generated in the fragile region 104 and is performed at a temperature higher than or equal to room temperature and lower than 400° C., for example. The oxide film 132 and the nitrogen-containing layer 121 may be bonded to each other while they are heated at a temperature in the above range. For this thermal treatment, a heating furnace such as a diffusion furnace or a resistance heating furnace, a rapid thermal annealing (RTA) apparatus, a microwave heating apparatus, or the like can be used.

In general, when thermal treatment is performed at the same time as or after the bonding of the oxide film 132 and the nitrogen-containing layer 121, dehydration reaction proceeds at the bonding interface and the bonding interfaces come closer to each other. Thus, the bonding is strengthened by strengthening of hydrogen bond or forming of a covalent bond. In order to promote the dehydration reaction, moisture generated at the bonding interface through the dehydration reaction should be removed by thermal treatment at high temperatures. In other words, when thermal treatment after the bonding is performed at low temperatures, moisture generated at the bonding interface through a dehydration reaction cannot be removed effectively; thus, the dehydration reaction does not progress and it is difficult to improve the bonding strength sufficiently.

On the other hand, when an oxide film containing a chlorine atom or the like is used as the oxide film 132, moisture can be absorbed and diffused in the oxide film 132. Therefore, even in the case where the thermal treatment after the bonding is performed at low temperatures, moisture generated at the bonding interface through a dehydration reaction can be absorbed and diffused in the oxide film 132 and the dehydration reaction can be promoted efficiently. In this case, even when a substrate having low heat resistance such as a glass substrate is used as the base substrate 120, the bonding strength between the oxide film 132 and the nitrogen-containing layer 121 can be sufficiently increased. Further, plasma treatment is performed by applying a bias voltage, whereby micropores are formed near the surface of the oxide film 132 so that moisture is absorbed and diffused effectively. Thus, the bonding strength of the oxide film 132 and the nitrogen-containing layer 121 can be increased even by low-temperature treatment.

Next, thermal treatment is performed to split the single crystal semiconductor substrate 100 at the fragile region 104, whereby the single crystal semiconductor layer 124 is provided over the base substrate 120 with the oxide film 132 and the nitrogen-containing layer 121 interposed therebetween (see FIG. 2G).

Due to temperature rise in the thermal treatment, the element added by the ion irradiation is separated out into microvoids which are formed in the fragile region 104, and internal pressure of the microvoids is increased. By the pressure increase, the microvoids in the fragile region 104 are changed in volume and a crack is generated in the fragile region 104. As a result, the single crystal semiconductor substrate 100 is split along the fragile region 104. Since the oxide film 132 is bonded to the nitrogen-containing layer 121 provided for the base substrate 120, the single crystal semiconductor layer 124 which is separated from the single crystal semiconductor substrate 100 is provided over the base substrate 120. Further, the temperature in the thermal treatment here is set so as not to exceed the strain point of the base substrate 120.

For this thermal treatment, a heating furnace such as a diffusion furnace or a resistance heating furnace, a rapid thermal annealing (RTA) apparatus, a microwave heating apparatus, or the like can be used. For example, in the case of using an RTA apparatus, the thermal treatment can be performed at a heating temperature of greater than or equal to 550° C. and less than or equal to 730° C., for a processing time of greater than or equal to 0.5 minutes and less than or equal to 60 minutes.

Note that, by the thermal treatment of FIG. 2G without the above-described thermal treatment for increasing the bonding strength between the oxide film 132 and the nitrogen-containing layer 121, the heat treatment step for increasing the bonding strength between the oxide film 132 and the nitrogen-containing layer 121 and the heat treatment step for splitting at the fragile region 104 may be performed at the same time.

By the method described in Embodiment 2, even in the case where the nitrogen-containing layer 121 is used as a bonding layer, the bonding strength between the base substrate 120 and the single crystal semiconductor layer 124 can be improved and reliability can be improved. As a result, an SOI substrate where the base substrate 120 and the single crystal semiconductor layer 124 are disposed in closer contact with each other and where diffusion of impurities to the single crystal semiconductor layer 124 formed over the base substrate 120 is suppressed can be obtained.

In addition, by providing the nitrogen-containing layer on the base substrate side and forming the oxide film containing a halogen atom such as a chlorine atom on the semiconductor substrate side, a manufacturing process can be simplified and impurity elements can be prevented from entering the semiconductor substrate before bonding the semiconductor substrate and the base substrate to each other. Further, by forming the oxide film containing a halogen atom such as a chlorine atom as a bonding layer to be provided on the semiconductor substrate side, the bonding strength can be improved by promoting dehydrogenation reaction efficiently even when the heat treatment after bonding is performed at low temperatures.

Next, an end portion of the single crystal semiconductor layer 124, an end portion of the nitrogen-containing layer 121, and an end portion of the oxide film 132 are removed by, for example, a photolithography technique and an etching technique.

First, a resist mask with a desired shape is formed over the single crystal semiconductor layer 124. In Embodiment 2, the end portion of the single crystal semiconductor layer 124, which has an uneven end face (edge portion), is removed. Therefore, the resist mask is formed so as to have a slightly smaller size than the single crystal semiconductor layer 124. The resist mask can be easily formed using a wafer edge light-exposure apparatus.

Next, the end portion of the single crystal semiconductor layer 124 is removed using the resist mask, whereby a single crystal semiconductor layer 136 is formed. The removal of the end portion of the single crystal semiconductor layer 124 is performed by, for example, etching. The etching can be performed by the method described in Embodiment 1.

Due to the step of splitting the single crystal semiconductor substrate 100 for the provision of the single crystal semiconductor layer 124, the end portion of the single crystal semiconductor layer 124 is destroyed because part of the single crystal semiconductor substrate 100 remains on the split plane of the single crystal semiconductor layer 124 or part of the single crystal semiconductor layer 124 is peeled off at the end portion of the single crystal semiconductor substrate 100. As a result, at the end portion of the single crystal semiconductor substrate 100, a space is formed between a bottom surface of the single crystal semiconductor layer 124 and a top surface of a layer below the single crystal semiconductor layer 124. Alternatively, due to the step of splitting the single crystal semiconductor substrate 100, the adhesion between the single crystal semiconductor layer 124 and the insulating layer 102 is decreased at the end portion of the single crystal semiconductor layer 124.

In a later step of irradiating this single crystal semiconductor layer 124 with a laser beam, peeling of the single crystal semiconductor layer 124 occurs at the end portion due to the change in stress of the single crystal semiconductor layer 124.

In view of the above, the end portion of the single crystal semiconductor layer 124 is removed before the laser irradiation in Embodiment 2. By the removal of the end portion, the end face of the end portion can be planarized and the peeling of the single crystal semiconductor layer due to the laser irradiation can be suppressed.

Moreover, in the case where the single crystal semiconductor layer 124 has a mark for product management (this mark is also called an identification number, a wafer identification number, a wafer number, an ID number, or the like), the removal of the end portion of the single crystal semiconductor layer 124 and the removal of a region of the single crystal semiconductor layer where the mark is formed may be performed by the same etching step.

Next, a nitrogen-containing layer 138 and an oxide film 140 are formed by removing an end portion of the nitrogen-containing layer 121 (including a portion provided at a side surface of the single crystal semiconductor substrate 100) and an end portion of the oxide film 132 with the use of the resist mask formed in the former step. The removal of the end portion of the nitrogen-containing layer 121 and the end portion of the oxide film 132 is performed by, for example, etching.

As the etching, dry etching or wet etching may be employed; in any case, the etching is preferably performed so as not to etch the base substrate 120. Preferably, the end portion of the nitrogen-containing layer 121 and the end portion of the oxide film 132 are removed by dry etching using the resist mask, whereby the nitrogen-containing layer 138 and the oxide film 140 are formed so as to have planar end faces (edge portions) (see FIG. 2E).

Note that the step of etching the nitrogen-containing layer 138 and the oxide film 140 may be omitted when each of the nitrogen-containing layer 138 and the oxide film 140 has a planar end face.

After that, the resist mask is removed.

Through the above steps, an SOI substrate where the single crystal semiconductor layer 136 is provided over the base substrate 120 with the oxide film 140 and the nitrogen-containing layer 138 interposed therebetween can be manufactured.

After that, a surface of the single crystal semiconductor layer 136 formed over the base substrate 120 is irradiated with a laser beam in a manner similar to Embodiment 1; thus, the surface of the single crystal semiconductor layer 136 is planarized and the crystallinity of a superficial portion of the single crystal semiconductor layer 136 is recovered (re-single-crystallized).

By the method described in Embodiment 2, film strip of the single crystal semiconductor layer from the end portion thereof due to the laser irradiation can be suppressed.

Although the oxide film 132 is formed over the single crystal semiconductor substrate 100 and the nitrogen-containing layer 121 is formed over the base substrate 120 in Embodiment 2, the present invention is not limited thereto. For example, the oxide film 132 and the nitrogen-containing layer 121 may be stacked in this order over the single crystal semiconductor substrate 100, and the surface of the nitrogen-containing layer 121 formed over the oxide film 132 may be bonded to the surface of the base substrate 120. In this case, the nitrogen-containing layer 121 may be provided either before or after the formation of the fragile region 104. Note that an oxide film (for example, a silicon oxide film) may be formed over the nitrogen-containing layer 121, and the surface of this oxide film and the surface of the base substrate 120 may be bonded to each other.

Note that, in the case where mixture of an impurity into the single crystal semiconductor layer 136 from the base substrate 120 does not lead to a problem, the surface of the oxide film 132 provided over the single crystal semiconductor substrate 100 and the surface of the base substrate 120 may be bonded to each other without providing the nitrogen-containing layer 121 over the base substrate 120. In this case, the step of forming the nitrogen-containing layer can be omitted.

Note that the structure described in Embodiment 2 can be implemented as appropriate in combination with any of the structures described in the Embodiments of this specification.

### Embodiment 3

Embodiment 3 describes a method for manufacturing a semiconductor device using the SOI substrate manufactured in accordance with the method described in Embodiment 2. Moreover, a display device to which the semiconductor device manufactured using the SOI substrate is applied is described.

In Embodiment 3, a method for manufacturing a semiconductor device using the SOI substrate manufactured in accordance with the method described in Embodiment 2 with reference to FIGS. 2A to 2E is described. Note that another SOI substrate manufactured in accordance with the method described in Embodiment 1 or another method described in Embodiment 2 can be used as the SOI substrate.

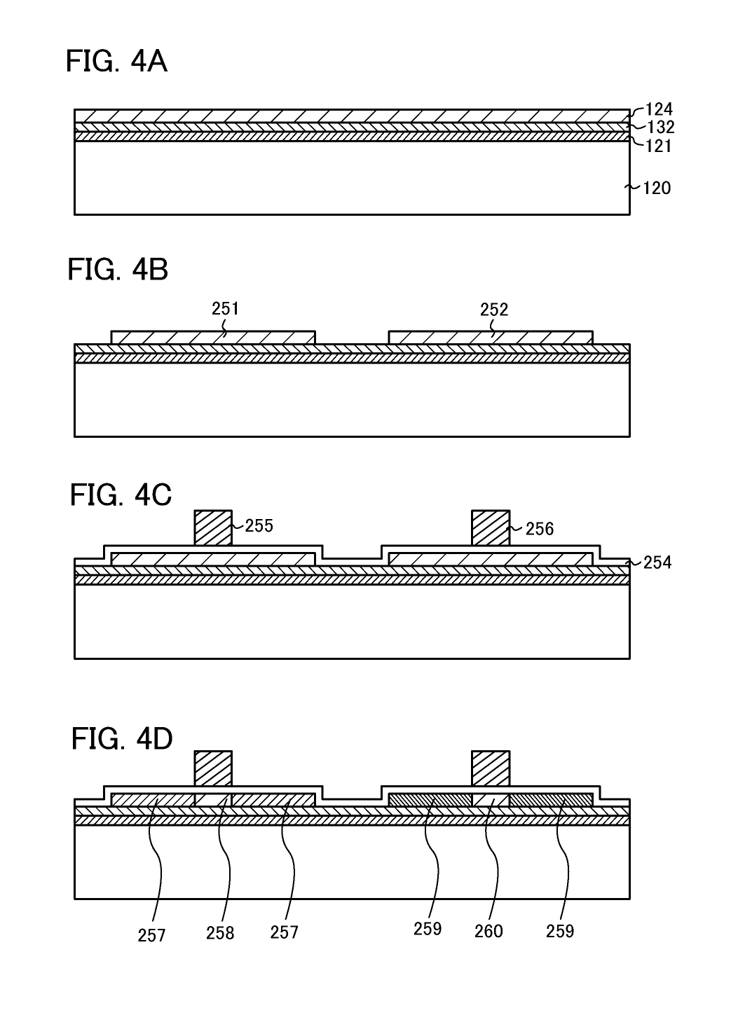

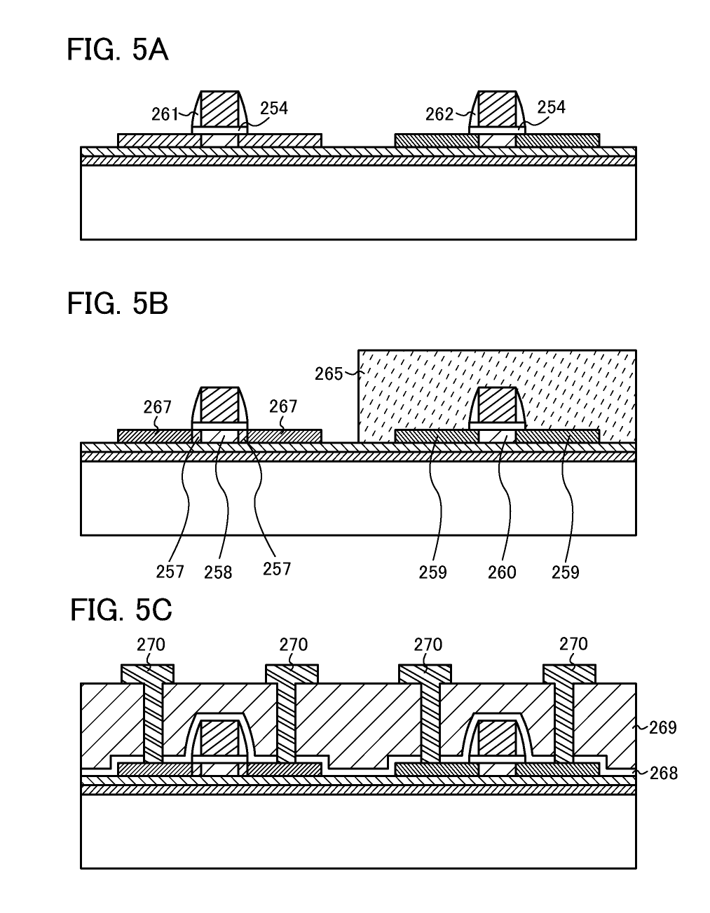

First, an example of a method for manufacturing an n-channel thin film transistor and a p-channel thin film transistor is described with reference to FIGS. 4A to 4D and FIGS. 5A to 5C. A variety of kinds of semiconductor devices can be formed by combining a plurality of thin film transistors (TFTs).

FIG. 4A is a cross-sectional view of the SOI substrate manufactured in accordance with the method described with reference to FIGS. 2A to 2E.

First, the single crystal semiconductor layer 136 is separated for each element by etching, whereby a semiconductor layer 251 and a semiconductor layer 252 are formed as illustrated in FIG. 4B. The semiconductor layer 251 is used for an n-channel TFT, and the semiconductor layer 252 is used for a p-channel TFT.

As illustrated in FIG. 4C, an insulating film 254 is formed over the semiconductor layers 251 and 252. Next, a gate electrode 255 is formed over the semiconductor layer 251 with the insulating film 254 interposed therebetween, and a gate electrode 256 is formed over the semiconductor layer 252 with the insulating film 254 interposed therebetween.

Before the single crystal semiconductor layer 136 is etched, an impurity element such as boron, aluminum, or gallium or an impurity element such as phosphorus or arsenic is preferably added to the single crystal semiconductor layer 136 in order to control the threshold voltage of the TFT. For example, an impurity element such as boron, aluminum, or gallium is added to a region where an n-channel TFT is to be formed, and an impurity element such as phosphorus or arsenic is added to a region where a p-channel TFT is to be formed.

Next, as illustrated in FIG. 4D, n-type low-concentration impurity regions 257 are formed in the semiconductor layer 251 and p-type high-concentration impurity regions 259 are formed in the semiconductor layer 252.

Specifically, first, the n-type low-concentration impurity regions 257 are formed in the semiconductor layer 251. For this purpose, the semiconductor layer 252 which is used for a p-channel TFT is covered with a resist mask. Then, an impurity element is added to the semiconductor layer 251 by an ion doping method or an ion implantation method. As the impurity element, phosphorus or arsenic may be added. In the step of adding the impurity element, the gate electrode 255 serves as a mask, and the n-type low-concentration impurity regions 257 are formed in the semiconductor layer 251 in a self-aligned manner. A region of the semiconductor layer 251 which overlaps with the gate electrode 255 serves as a channel formation region 258.

Next, after the mask that covers the semiconductor layer 252 is removed, the semiconductor layer 251 where an n-channel TFT is to be formed is covered with a resist mask. Then, an impurity element is added to the semiconductor layer 252 by an ion doping method or an ion implantation method. As the impurity element, boron may be added. In the step of adding the impurity element, the gate electrode 256 serves as a mask, and the p-type high-concentration impurity regions 259 are formed in the semiconductor layer 252 in a self-aligned manner. The high-concentration impurity regions 259 function as a source region and a drain region. A region of the semiconductor layer 252 which overlaps with the gate electrode 256 serves as a channel formation region 260. Although the method in which the p-type high-concentration impurity regions 259 are formed after the n-type low-concentration impurity regions 257 are formed is described here, the p-type high-concentration impurity regions 259 may be formed before the n-type low-concentration impurity regions 257 are formed.

Next, after the mask that covers the semiconductor layer 251 is removed, an insulating film is formed by a plasma CVD method or the like as a single layer or a stack of layers, which includes a nitrogen compound such as silicon nitride or an oxide such as silicon oxide. This insulating film is anisotropically etched in a perpendicular direction, whereby sidewall insulating films 261 and 262 are formed in contact with side surfaces of the gate electrodes 255 and 256, respectively as illustrated in FIG. 5A. In this anisotropic etching, the insulating film 254 is also etched.

Next, as illustrated in FIG. 5B, the semiconductor layer 252 is covered with a resist 265. In order to form high-concentration impurity regions serving as a source region and a drain region in the semiconductor layer 251, an impurity element is added into the semiconductor layer 251 at a high dose by an ion implantation method or an ion doping method. In the step of adding the impurity element, the gate electrode 255 and the sidewall insulating film 261 function as masks, whereby n-type high-concentration impurity regions 267 are formed in the semiconductor layer 251.

Next, after the mask that covers the semiconductor layer 252 is removed, thermal treatment for activating the impurity element is performed.

After the thermal treatment for the activation, an insulating film 268 containing hydrogen is formed as illustrated in FIG. 5C. The insulating film 268 can be formed by depositing silicon nitride or silicon nitride oxide by a plasma CVD method at a process temperature of 350° C. or lower. After the insulating film 268 is formed, thermal treatment is performed at a temperature of 350° C. or higher and 450° C. or lower, so that hydrogen contained in the insulating film 268 diffuses into the semiconductor layers 251 and 252. The supply of hydrogen to the semiconductor layers 251 and 252 makes it possible to effectively compensate defects that might serve as trapping centers in the semiconductor layers 251 and 252 and at an interface between the semiconductor layer 251 and the insulating film 254 and an interface between the semiconductor layer 252 and the insulating film 254.

After that, an interlayer insulating film 269 is formed. The interlayer insulating film 269 can be formed as a single layer or a stack of layers using an insulating film containing an inorganic material, such as a silicon oxide film or a borophosphosilicate glass (BPSG) film, or an organic resin film containing polyimide, acrylic, or the like.

After contact holes are formed through the interlayer insulating film 269, wirings 270 are formed as illustrated in FIG. 5C. The wirings 270 can be formed using a conductive film with a three-layer structure in which a low-resistance metal film such as an aluminum film or an aluminum alloy film is interposed between barrier metal films. The barrier metal films can each be formed using a metal film of molybdenum, chromium, titanium, or the like.

Through the above steps, a semiconductor device including the n-channel TFT and the p-channel TFT can be completed.

Although the method for manufacturing TFTs is described with reference to FIGS. 4A to 4D and FIGS. 5A to 5C, a semiconductor device with high added value can be manufactured by additionally forming a variety of semiconductor elements such as a capacitor or a resistor together with the TFTs. A specific example of the semiconductor device is described below with reference to drawings.

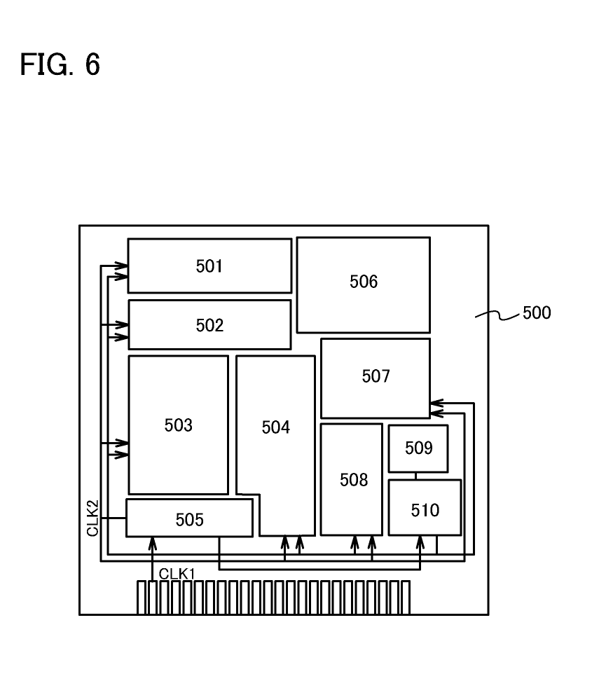

First, a microprocessor is described as an example of the semiconductor device. FIG. 6 is a block diagram illustrating a structure example of a microprocessor 500.

The microprocessor 500 includes an arithmetic logic unit (also referred to as an ALU) 501, an ALU controller 502, an instruction decoder 503, an interrupt controller 504, a timing controller 505, a register 506, a register controller 507, a bus interface (Bus I/F) 508, a read-only memory (also referred to as a ROM) 509, and a memory interface 510.

An instruction input to the microprocessor 500 via the bus interface 508 is input to the instruction decoder 503 and decoded. Then, the instruction is input to the ALU controller 502, the interrupt controller 504, the register controller 507, and the timing controller 505. The ALU controller 502, the interrupt controller 504, the register controller 507, and the timing controller 505 perform various controls based on the decoded instruction.

The ALU controller 502 generates a signal for controlling the operation of the ALU 501. While the microprocessor 500 is executing a program, the interrupt controller 504 processes an interrupt request from an external input and output device or a peripheral circuit. The interrupt controller 504 judges the priority of the interrupt request or a mask state, and processes the interrupt request. The register controller 507 generates an address of the register 506, and reads and writes data from and into the register 506 in accordance with the state of the microprocessor 500. The timing controller 505 generates signals for controlling timing of operation of the ALU 501, the ALU controller 502, the instruction decoder 503, the interrupt controller 504, and the register controller 507. For example, the timing controller 505 is provided with an internal clock generator for generating an internal clock signal CLK2 based on a reference clock signal CLK1. As illustrated in FIG. 6, the internal clock signal CLK2 is input to other circuits.

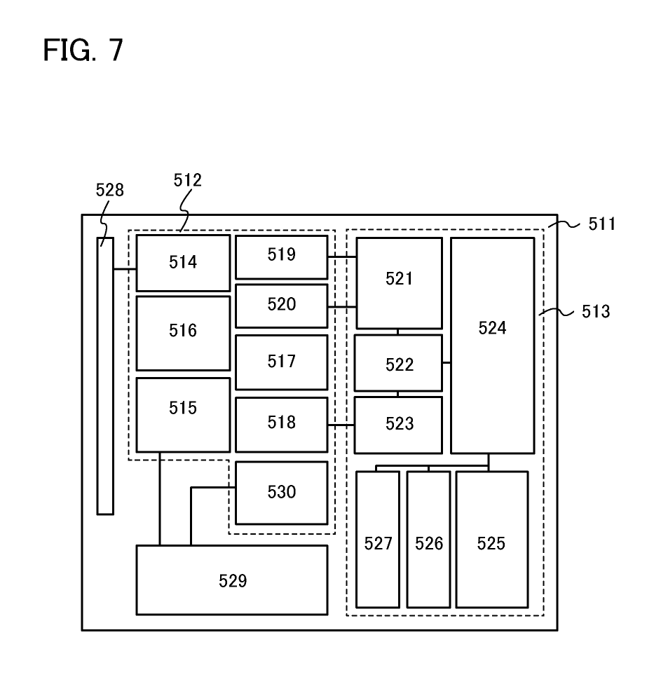

Next, an embodiment of a semiconductor device having a function of transmitting/receiving data without contact and also having an arithmetic function is described. As an example of such a semiconductor device, a computer which operates by transmitting/receiving signals to/from an external device through wireless communication (this computer is hereinafter referred to as an RFCPU) is described. FIG. 7 is a block diagram illustrating a structure example of an RFCPU.

As illustrated in FIG. 7, an RFCPU 511 includes an analog circuit portion 512, a digital circuit portion 513, an antenna 528, and a capacitor portion 529. The analog circuit portion 512 includes a resonant circuit 514 having a resonant capacitor, a rectifier circuit 515, a constant voltage circuit 516, a reset circuit 517, an oscillator circuit 518, a demodulation circuit 519, a modulation circuit 520 and a power supply control circuit 530. The digital circuit portion 513 includes an RF interface 521, a control register 522, a clock controller 523, an interface 524, a central processing unit (CPU) 525, a random access memory (RAM) 526, and a read only memory (ROM) 527.

The operation of the RFCPU 511 is briefly described below. An induced electromotive force is generated in the resonant circuit 514 based on a signal received by the antenna 528. The induced electromotive force is stored in a capacitor portion 529 via the rectifier circuit 515. This capacitor portion 529 is preferably formed using a capacitor such as a ceramic capacitor or an electric double-layer capacitor. The capacitor portion 529 is not necessarily provided over the same substrate as the RFCPU 511 and may be incorporated in the RFCPU 511 as a component.

The reset circuit 517 generates a signal that resets to initialize the digital circuit portion 513. For example, the reset circuit 517 generates, as a reset signal, a signal which rises with delay after an increase in power supply voltage. The oscillator circuit 518 changes the frequency and duty ratio of a clock signal in accordance with a control signal generated by the constant voltage circuit 516. The demodulation circuit 519 demodulates a received signal, and the modulation circuit 520 modulates data to be transmitted.

For example, the demodulator circuit 519 is formed with a low-pass filter and binarizes a received signal of amplitude shift keying (ASK) system based on the variation in its amplitude. In order to vary the amplitude of an amplitude shift keying (ASK) transmission signal and transmit the signal, the modulator circuit 520 changes the amplitude of a communication signal by changing a resonance point of the resonant circuit 514.

The clock controller 523 generates a control signal for changing the frequency and the duty ratio of the clock signal in accordance with the power supply voltage or current consumption in the CPU 525. The power supply voltage is monitored by the power supply control circuit 530.

A signal that is input to the RFCPU 511 from the antenna 528 is demodulated by the demodulation circuit 519, and then divided into a control command, data, and the like by the RF interface 521. The control command is stored in the control register 522. The control command includes reading of data stored in the ROM 527, writing of data into the RAM 526, an arithmetic instruction to the CPU 525, and the like.

The CPU 525 accesses the ROM 527, the RAM 526, and the control register 522 via the interface 524. The interface 524 functions to generate an access signal for any of the ROM 527, the RAM 526, and the control register 522 based on an address which the CPU 525 requests.

As an arithmetic method of the CPU 525, a method can be employed in which an operating system (OS) is stored in the ROM 527 and a program is read and executed at the time of starting the operation. Alternatively, a method in which a circuit dedicated to arithmetic is formed and an arithmetic process is conducted using hardware can be employed. In a method in which both hardware and software are used, part of arithmetic processing can be conducted by a circuit dedicated to arithmetic, and the other part of the arithmetic processing can be conducted by the CPU 525 with use of a program.

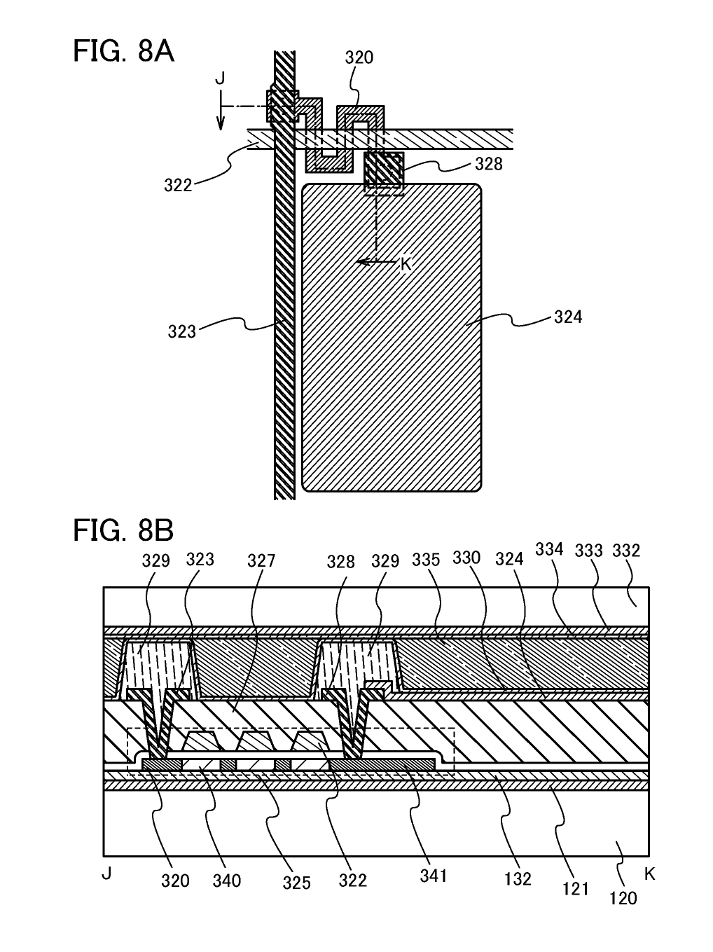

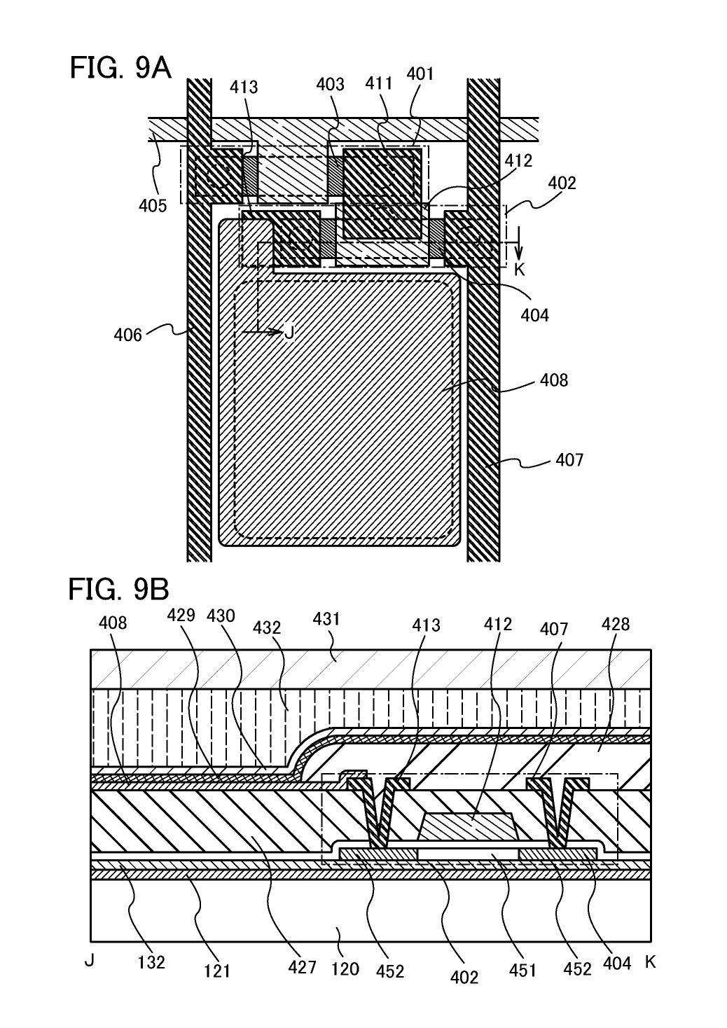

Next, an example of a structure of a display device to which the semiconductor device manufactured using the above SOI substrate is applied is described with reference to FIGS. 8A and 8B and FIGS. 9A and 9B.

FIGS. 8A and 8B are drawings for describing an example of a liquid crystal display device. FIG. 8A is a plan view of a pixel of the liquid crystal display device, and FIG. 8B is a cross-sectional view taken along section line J-K in FIG. 8A.

As illustrated in FIG. 8A, the pixel includes a single crystal semiconductor layer 320, a scan line 322 intersecting with the single crystal semiconductor layer 320, a signal line 323 intersecting with the scan line 322, a pixel electrode 324, and an electrode 328 which electrically connects the pixel electrode 324 to the single crystal semiconductor layer 320. The single crystal semiconductor layer 320 is a layer formed using the single crystal semiconductor layer provided over the base substrate 120 and is included in a TFT 325 of the pixel.

As the SOI substrate, the SOI substrate manufactured in accordance with the method described in Embodiment 2 with reference to FIGS. 2A to 2E is used here. Note that another SOI substrate manufactured in accordance with the method described in Embodiment 1 or another method described in Embodiment 2 can be used as the SOI substrate.

As illustrated in FIG. 8B, the single crystal semiconductor layer 320 is provided over the base substrate 120 with the oxide film 132 and the nitrogen-containing layer 121 interposed therebetween. As the base substrate 120, a glass substrate can be used. The single crystal semiconductor layer 320 of the TFT 325 is formed by etching a single crystal semiconductor layer of the SOI substrate so that the layer is divided for each element. A channel formation region 340 and n-type high-concentration impurity regions 341 to which impurity elements are added are formed in the single crystal semiconductor layer 320. A gate electrode of the TFT 325 is included in the scan line 322 and one of a source electrode and a drain electrode of the TFT 325 is included in the signal line 323.

Over an interlayer insulating film 327, the signal line 323, the pixel electrode 324, and the electrode 328 are provided. Columnar spacers 329 are formed over the interlayer insulating film 327. An alignment film 330 is formed to cover the signal line 323, the pixel electrode 324, the electrode 328, and the columnar spacers 329. A counter substrate 332 is provided with a counter electrode 333 and an alignment film 334 that covers the counter electrode. The columnar spacers 329 are formed to keep the space between the base substrate 120 and the counter substrate 332. A liquid crystal layer 335 is formed in the space formed by the columnar spacers 329. The interlayer insulating film 327 has a depression at the connection portion between the high-concentration impurity regions 341 and each of the signal line 323 and the electrode 328 due to formation of contact holes; therefore, orientation of liquid crystals in the liquid crystal layer 335 is easily disordered at this connection portion. Therefore, the columnar spacers 329 are formed in this connection portion, so that the disorder of the liquid crystal is prevented.

Next, an example of an electroluminescent display device (hereinafter referred to as an “EL display device”) is described with reference to FIGS. 9A and 9B. FIG. 9A is a plan view of a pixel of the EL display device, and FIG. 9B is a cross-sectional view taken along section line J-K in FIG. 9A.

As illustrated in FIG. 9A, the pixel includes a selection transistor 401, a display control transistor 402, a scan line 405, a signal line 406, a current supply line 407, and a pixel electrode 408. Each pixel is provided with a light emitting element having a structure in which a layer containing an electroluminescent material (EL layer) is interposed between a pair of electrodes. One electrode of the light-emitting element is the pixel electrode 408. Further, a semiconductor layer 403 forms a channel formation region, a source region, and a drain region of the selection transistor 401. In a semiconductor layer 404, a channel formation region, a source region, and a drain region of the display control transistor 402 are formed. The semiconductor layers 403 and 404 are formed using the single crystal semiconductor layer that is provided over the base substrate.

In the selection transistor 401, a gate electrode is included in the scan line 405, one of a source electrode and a drain electrode is included in the signal line 406, and the other thereof is formed as an electrode 411. In the display control transistor 402, a gate electrode 412 is electrically connected to the electrode 411, one of a source electrode and a drain electrode is formed as an electrode 413 which is electrically connected to the pixel electrode 408, and the other thereof is included in the current supply line 407.

The display control transistor 402 is a p-channel TFT. As illustrated in FIG. 9B, in the semiconductor layer 404, a channel formation region 451 and p-type high-concentration impurity regions 452 are formed. As the SOI substrate, the SOI substrate manufactured in accordance with the method of Embodiment 1 or 2 is used.

An interlayer insulating film 427 is formed so as to cover the gate electrode 412 of the display control transistor 402. The signal line 406, the current supply line 407, the electrodes 411 and 413, and the like are formed over the interlayer insulating film 427. Moreover, the pixel electrode 408 which is electrically connected to the electrode 413 is formed over the interlayer insulating film 427. The pixel electrode 408 is surrounded by a partition wall layer 428, which has an insulating property, at the periphery. An EL layer 429 is formed over the pixel electrode 408, and a counter electrode 430 is formed over the EL layer 429. A counter substrate 431 is provided as a reinforcing plate and is fixed to the base substrate 120 by a resin layer 432.

The grayscale of the EL display device is controlled by either a current drive method where the luminance of the light-emitting element is controlled by current or a voltage drive method where the luminance is controlled by voltage. The current drive method is difficult to employ when transistors have characteristics which largely vary from pixel to pixel. In order to employ the current drive method, a correction circuit which corrects characteristic variation is needed. When the EL display device is manufactured by a manufacturing method including a manufacturing process of an SOI substrate, the selecting transistor 401 and the display control transistor 402 do not have variation in characteristics from pixel to pixel. Accordingly, the current drive method can be employed in the Embodiment 3.

### Embodiment 4

Embodiment 4 describes an electronic appliance in which the SOI substrate manufactured by the method described in Embodiment 1 or 2 is used.

Examples of electric appliances include cameras such as video cameras and digital cameras; navigation systems; sound reproduction devices (such as car audio systems and audio components); computers; game machines; portable information terminals (such as mobile computers, cellular phones, portable game machines, and electronic book devices); image reproduction devices each provided with a storage medium (specifically, devices each provided with a display device that reproduces the audio data stored in a storage medium such as a digital versatile disc (DVD) and displays image data stored therein); and the like. A structure of a cellular phone is described below as an example thereof.

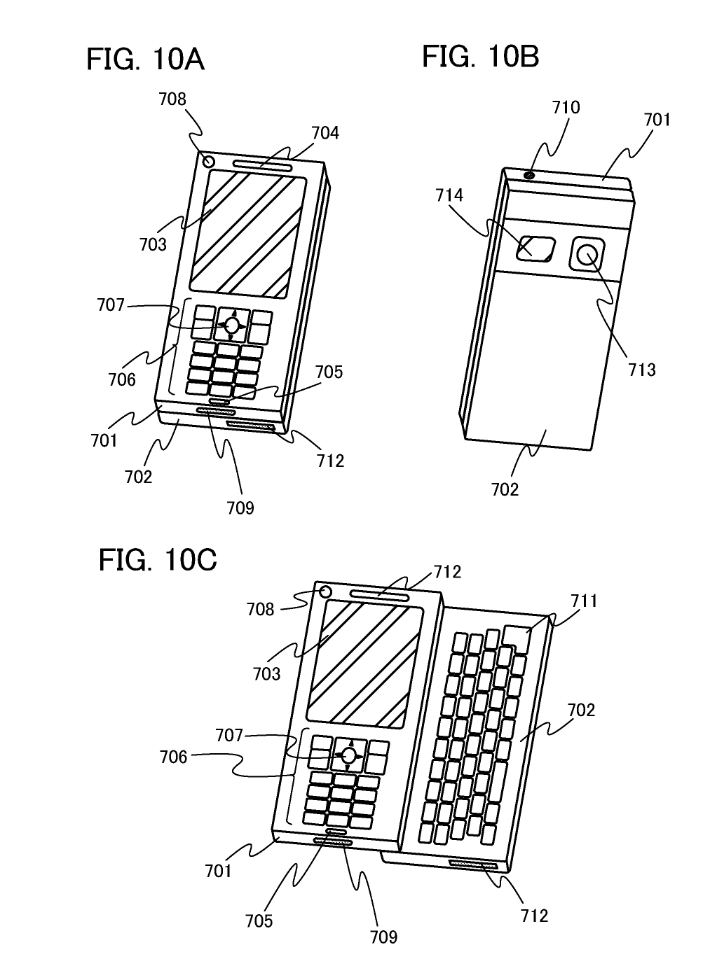

FIGS. 10A to 10C illustrate an example of a cellular phone in which the SOI substrate manufactured by the method described in Embodiment 1 or 2 is used; FIG. 10A is a front view, FIG. 10B is a rear view, and FIG. 10C is a front view when two housings are slid open. The cellular phone has two housings, a housing 701 and a housing 702. The cellular phone is a so-called smartphone which has both functions of a cellular phone and a portable information terminal, and incorporates a computer and can perform a variety of data processing in addition to voice calls.

The cellular phone includes the housing 701 and the housing 702. The housing 701 includes a display portion 703, a speaker 704, a microphone 705, operation keys 706, a pointing device 707, a front camera lens 708, a jack 709 for an external connection terminal, an earphone terminal 710, and the like. The housing 702 includes a keyboard 711, an external memory slot 712, a rear camera 713, a light 714, and the like. The antenna is incorporated in the housing 701.

In addition to the above components, the cellular phone may incorporate a noncontact IC chip, a small storage device, and the like.

The housings 701 and 702 which overlap with each other (see FIG. 10A) can be developed by sliding as illustrated in FIG. 10C. In the display portion 703, a display panel or a display device in which the SOI substrate manufactured by the method described in Embodiment 1 or 2 is used can be incorporated. Since the front camera lens 708 is provided in the same plane as the display portion 703, the cellular phone can be used as a videophone. Further, a still image and a moving image can be taken with the rear camera 713 and the light 714, using the display portion 703 as a viewfinder.

With the use of the speaker 704 and the microphone 705, the cellular phone can be used as a sound recording device (recorder) or a sound reproduction device. With use of the operation keys 706, operation of incoming and outgoing calls, simple information input for electronic mail or the like, scrolling of a screen displayed on the display portion, cursor motion for selecting information to be displayed on the display portion, and the like are possible.

When much information needs to be treated, for example, when the document is prepared or the cellular phone is used as a portable information terminal, it is convenient to use the keyboard 711. In the case where the cellular phone is used as a portable information terminal, smooth operation can be performed with the keyboard 711 and the pointing device 707. The jack 709 for an external connection terminal can be connected to an AC adapter or a variety of cables such as a USB cable, and charging and data communication with a personal computer or the like is possible. Further, by inserting a storage medium in the external memory slot 712, a larger amount of data can be stored and transferred.

The rear face of the housing 702 is provided with the rear camera 713 and the light 714 (see FIG. 10B), and still images and moving images can be taken using the display portion 703 as a viewfinder.

The cellular phone may have an infrared communication function, a USB port, a function of receiving one segment television broadcast, a noncontact IC chip, an earphone jack, or the like, in addition to the above-described functions and structures.

As described above, the reliability can be increased when the display portion of the electronic appliance incorporates the SOI substrate manufactured by the method described in Embodiment 1 or 2.

Note that the structure described in Embodiment 4 can be implemented as appropriate in combination with any of the structures described in the Embodiments of this specification.

### Example 1

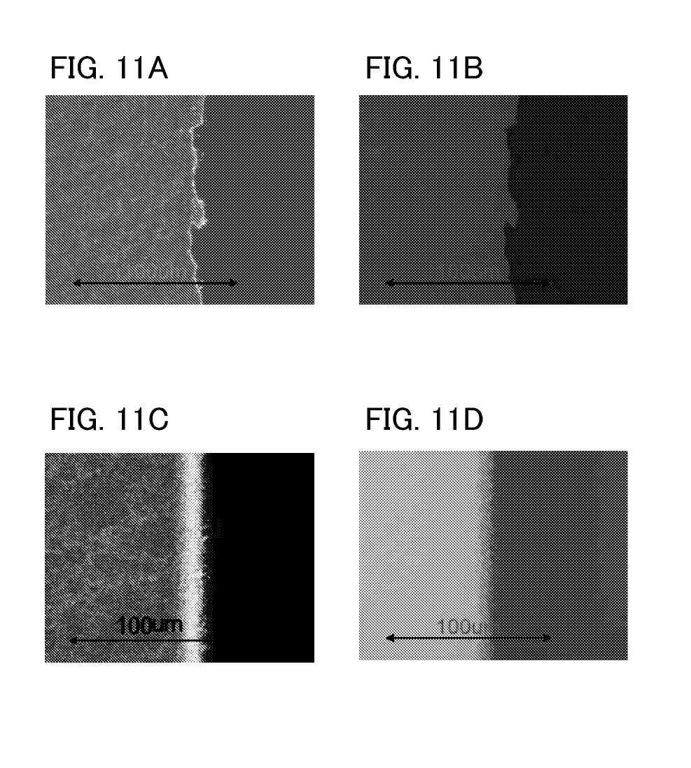

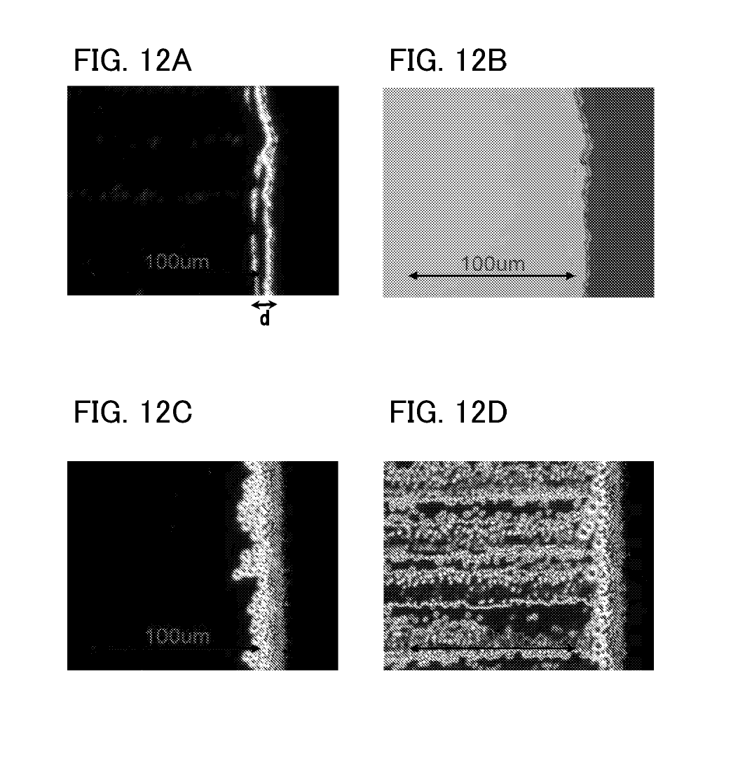

Example 1 describes how the removal of the end portion of the single crystal semiconductor layer affects the single crystal semiconductor layer formed in accordance with the method described in Embodiment 2, with reference to optical micrographs of FIGS. 11A to 11B, and FIGS. 12A to 12D. Note that FIGS. 11A and 11C and FIGS. 12A and 12C are optical micrographs obtained by observation of bright field and FIGS. 11B and 11D and FIGS. 12B and 12D are optical micrographs obtained by observation of dark field.

A method for manufacturing each of Sample A, Sample B, Sample C, and Sample D which are observed in Example 1 is described below. Since the manufacturing method up to the step of removing an end portion of a single crystal semiconductor layer is the same in each of Sample A, Sample B, Sample C, and Sample D, the method is collectively described.

As a single crystal semiconductor substrate, a single crystal silicon substrate having a rectangular shape with a size of 5 inches on a side was used. As a base substrate, a non-alkali glass substrate (product name: AN100) having a thickness of 0.7 mm was used.

First, an oxide film was formed on a surface of the single crystal silicon substrate by performing thermal oxidation treatment on the single crystal silicon substrate in an oxidative atmosphere to which chlorine was added. In Example 1, the thermal oxidation treatment was performed at 950° C. for 210 minutes in an oxidative atmosphere in which hydrogen chloride (HCl) was contained by 3 vol. % with respect to oxygen. In this manner, the oxide film was formed to a thickness of 100 nm.

Next, the single crystal silicon substrate was irradiated with hydrogen ions through the oxide film by using an ion doping apparatus; thus, a fragile region was formed at a predetermined depth from the surface of the single crystal silicon substrate.

Next, a surface of the oxide film and a surface of the base substrate were disposed so as to face each other; then, the single crystal silicon substrate and the base substrate were bonded to each other with the oxide film interposed therebetween.

Next, thermal treatment was performed so that the single crystal silicon substrate was split along the fragile region; thus, the SOI substrate where the single crystal silicon layer was provided over the base substrate with the oxide film interposed therebetween was completed. The heat treatment was performed in a heating furnace at 200° C. for 2 hours and then at 600° C. for 2 hours. The thickness of the single crystal silicon layer after the split was 140 nm.

The single crystal silicon layer after the split was etched (etched-back) as a whole, so that the thickness of the single crystal silicon layer was 110 nm. The SOI substrate manufactured in this manner is defined as Sample A.

FIGS. 11A and 11B are optical micrographs of end portions of Sample A. From the observation of FIGS. 11A and 11B, the end portion of the single crystal silicon layer has an uneven end face.

Next, the end portion of the single crystal silicon layer and the end portion of the oxide film, which are obtained through the above process, were removed by etching. First, a resist mask was formed over the single crystal silicon layer by a photolithography method. The resist mask was formed over the single crystal silicon layer but formed so as not to cover the end portion of the single crystal silicon layer because the end portion having the uneven end face would be removed. In Example 1, the resist mask was formed so that the distance between the peripheral edge of the single crystal silicon layer and the peripheral edge of the resist mask is approximately 8 mm.

Next, the etching was performed on the end portion of the single crystal silicon layer and the end portion of the oxide film in this order using the resist mask. As the etching, dry etching was performed using a parallel-plate reactive ion etching (RIE) apparatus.

First, the single crystal silicon layer was etched for approximately 120 seconds under the condition where the bias power of a parallel plate was 300 W, the pressure in a chamber was 200 mTorr, a fluorine-based gas was used as an etching gas, and the gas flow rate was SF₆:He=20:20 (sccm); thus, the end portion of the single crystal silicon layer was removed. Next, the oxide film was etched for 2 minutes under the condition where the bias power of a parallel plate was 150 W, the pressure in a chamber was 200 mTorr, a fluorine-based gas was used as an etching gas, and the gas flow rate was SF₆:He=20:20 (sccm); thus, the end portion of the oxide film was removed. After the etching as above, the single crystal silicon layer with a length of 110 mm on a side was obtained. The SOI substrate manufactured in this manner is defined as Sample B.

FIGS. 11C and 11D are optical micrographs of end portions of Sample B. From the observation of FIGS. 11C and 11D, the end portion of the single crystal silicon layer which includes the uneven end face became planar by the removal of the end portion and the single crystal silicon layer was formed to have a rectangular shape with a linear cross section on each side.

Next, the single crystal silicon layer was processed with hydrofluoric acid for 110 seconds, so that an oxide film including a native oxide film formed on a surface of the single crystal silicon layer was removed.

Then, the surface of the single crystal silicon layer was irradiated with a laser beam, so that the surface of the single crystal silicon layer was planarized and the crystallinity of a superficial portion of the single crystal silicon layer was recovered. As a laser, a XeCl excimer laser with a repetition rate of 30 Hz and a wavelength of 308 nm was used, and the laser beam and the single crystal silicon layer were moved relative to each other; in this manner, the surface of the single crystal silicon layer was irradiated by the scanning of the laser beam. By the irradiation with the laser beam through an optical system, a linear beam spot with a length of about 300 μm in a short axis direction was obtained on the surface of the single crystal silicon layer. Here, the scanning speed was set to 1.0 mm/s and the irradiation with the laser beam was performed in a nitrogen atmosphere.

Next, the single crystal silicon layer was etched (etched-back) as a whole; as a result, the thickness thereof was 60 nm After that, heat treatment was performed at 600° C. for 4 hours in a nitrogen atmosphere. The SOI substrate manufactured in this manner is defined as Sample D.

FIGS. 12C and 12D are optical micrographs of end portions of Sample D. For comparison, FIGS. 12A and 12B are optical micrographs of end portions of Sample C, which is the SOI substrate obtained by irradiating Sample A with a laser beam under the above condition.

According to the observation, Sample C whose end portion was not removed has an uneven end face at the end portion of the single crystal silicon layer. In Sample A (see FIGS. 11A and 11B), peeling of the single crystal silicon layer at the end portion is not observed; however, in Sample C after the laser irradiation, peeling thereof is observed in a portion denoted with “d” in FIGS. 12A and 12B.

On the other hand, in Sample D, which was manufactured through the step of removing the end portion, the end face of the single crystal silicon layer is planar according to the observation. Moreover, in Sample D, peeling of the film at the end portion does not occur even after the laser irradiation, as can be observed in FIGS. 12C and 12D.

The comparison between FIGS. 12A and 12B and FIGS. 12C and 12D indicates that the end face of the single crystal silicon layer was planarized and peeling of the film by the laser irradiation was suppressed by the removal of the end portion of the single crystal silicon layer.

This application is based on Japanese Patent Application serial No. 2009-000239 filed with Japan Patent Office on Jan. 5, 2009, the entire contents of which are hereby incorporated by reference.

What is claimed is:

1. A method for manufacturing an SOI substrate, comprising the steps of:
forming a fragile region in a single crystal semiconductor substrate by irradiating the single crystal semiconductor substrate with an accelerated ion;
bonding the single crystal semiconductor substrate to a base substrate with an insulating layer interposed therebetween;
forming a single crystal semiconductor layer over the base substrate with the insulating layer interposed therebetween, by splitting the single crystal semiconductor substrate at the fragile region;
removing an end portion of the single crystal semiconductor layer; and
irradiating with a laser beam a surface of the single crystal semiconductor layer after removing the end portion of the single crystal semiconductor layer.

2. The method for manufacturing an SOI substrate according to claim 1, further comprising the step of removing an end portion of the insulating layer after removing the end portion of the single crystal semiconductor layer and before irradiating with the laser beam.

3. The method for manufacturing an SOI substrate according to claim 1, wherein the insulating layer is a single layer or a stack of layers, which includes a silicon oxide film, a silicon oxynitride film, a silicon nitride film, or a silicon nitride oxide film.

4. The method for manufacturing an SOI substrate according to claim 1, wherein the single crystal semiconductor substrate is split at the fragile region by performing thermal treatment.

5. The method for manufacturing an SOI substrate according to claim 1, wherein the surface of the single crystal semiconductor layer is irradiated with the laser beam after removing the end portion of the single crystal semiconductor layer, so that the surface of the single crystal semiconductor layer is planarized.

6. The method for manufacturing an SOI substrate according to claim 1, wherein the surface of the single crystal semiconductor layer is irradiated with the laser beam after removing the end portion of the single crystal semiconductor layer, so that crystallinity of a superficial portion of the single crystal semiconductor layer is recovered.

7. The method for manufacturing an SOI substrate according to claim 1, wherein the end portion of the single crystal semiconductor layer is removed by etching.

8. The method for manufacturing an SOI substrate according to claim 1, wherein the base substrate is a glass substrate.

9. A method for manufacturing an SOI substrate, comprising the steps of:
forming an oxide film on a surface of a single crystal semiconductor substrate;
forming a fragile region in the single crystal semiconductor substrate by irradiating the single crystal semiconductor substrate with an accelerated ion through the oxide film;
bonding the single crystal semiconductor substrate to a base substrate with the oxide film and a nitrogen-containing layer interposed therebetween;
forming a single crystal semiconductor layer over the base substrate with the oxide film and the nitrogen-containing layer interposed therebetween, by splitting the single crystal semiconductor substrate at the fragile region;
removing an end portion of the single crystal semiconductor layer; and
irradiating with a laser beam a surface of the single crystal semiconductor layer after removing the end portion of the single crystal semiconductor layer.

10. The method for manufacturing an SOI substrate according to claim 9, further comprising the step of removing an end portion of the oxide film and an end portion of the nitrogen-containing layer after removing the end portion of the single crystal semiconductor layer and before irradiating with the laser beam.

11. The method for manufacturing an SOI substrate according to claim 9, wherein the oxide film is formed by performing thermal treatment on the single crystal semiconductor substrate in an oxidative atmosphere to which halogen is added.

12. The method for manufacturing an SOI substrate according to claim 9, wherein the nitrogen-containing layer is a silicon nitride film or a silicon nitride oxide film.

13. The method for manufacturing an SOI substrate according to claim 9, wherein the single crystal semiconductor substrate is split at the fragile region by performing thermal treatment.

14. The method for manufacturing an SOI substrate according to claim 9, wherein the surface of the single crystal semiconductor layer is irradiated with the laser beam after removing the end portion of the single crystal semiconductor layer, so that the surface of the single crystal semiconductor layer is planarized.

15. The method for manufacturing an SOI substrate according to claim 9, wherein the surface of the single crystal semiconductor layer is irradiated with the laser beam after removing the end portion of the single crystal semiconductor layer, so that crystallinity of a superficial portion of the single crystal semiconductor layer is recovered.

16. The method for manufacturing an SOI substrate according to claim 9, wherein the end portion of the single crystal semiconductor layer is removed by etching.

17. The method for manufacturing an SOI substrate according to claim 9, wherein the base substrate is a glass substrate.

18. A method for manufacturing a semiconductor device, comprising the steps of:
forming a fragile region in a single crystal semiconductor substrate by irradiating the single crystal semiconductor substrate with an accelerated ion;
bonding the single crystal semiconductor substrate to a base substrate with an insulating layer interposed therebetween;
forming a single crystal semiconductor layer over the base substrate with the insulating layer interposed therebetween, by splitting the single crystal semiconductor substrate at the fragile region;
removing an end portion of the single crystal semiconductor layer;
irradiating with a laser beam a surface of the single crystal semiconductor layer after removing the end portion of the single crystal semiconductor layer;
etching the single crystal semiconductor layer after irradiating with the laser beam, so that the single crystal semiconductor layer is divided into each element; and
forming a transistor using the divided single crystal semiconductor layer.

19. The method for manufacturing a semiconductor device according to claim 18, further comprising the step of removing an end portion of the insulating layer after removing the end portion of the single crystal semiconductor layer and before irradiating with the laser beam.

20. The method for manufacturing a semiconductor device according to claim 18, wherein the insulating layer is a single layer or a stack of layers, which includes a silicon oxide film, a silicon oxynitride film, a silicon nitride film, or a silicon nitride oxide film.

21. The method for manufacturing a semiconductor device according to claim 18, wherein the single crystal semiconductor substrate is split at the fragile region by performing thermal treatment.

22. The method for manufacturing a semiconductor device according to claim 18, wherein the surface of the single crystal semiconductor layer is irradiated with the laser beam after removing the end portion of the single crystal semiconductor layer, so that the surface of the single crystal semiconductor layer is planarized.

23. The method for manufacturing a semiconductor device according to claim 18, wherein the surface of the single crystal semiconductor layer is irradiated with the laser beam after removing the end portion of the single crystal semiconductor layer, so that crystallinity of a superficial portion of the single crystal semiconductor layer is recovered.

24. The method for manufacturing a semiconductor device according to claim 18, wherein the end portion of the single crystal semiconductor layer is removed by etching.

25. The method for manufacturing a semiconductor device according to claim 18, wherein the base substrate is a glass substrate.

26. A method for manufacturing a semiconductor device, comprising the steps of:
forming an oxide film on a surface of a single crystal semiconductor substrate;
forming a fragile region in the single crystal semiconductor substrate by irradiating the single crystal semiconductor substrate with an accelerated ion through the oxide film;
bonding the single crystal semiconductor substrate to a base substrate with the oxide film and a nitrogen-containing layer interposed therebetween;
forming a single crystal semiconductor layer over the base substrate with the oxide film and the nitrogen-containing layer interposed therebetween, by splitting the single crystal semiconductor substrate at the fragile region;
removing an end portion of the single crystal semiconductor layer;
irradiating with a laser beam a surface of the single crystal semiconductor layer after removing the end portion of the single crystal semiconductor layer;
etching the single crystal semiconductor layer after irradiating with the laser beam, so that the single crystal semiconductor layer is divided into each element; and
forming a transistor using the divided single crystal semiconductor layer.

27. The method for manufacturing a semiconductor device according to claim 26, further comprising the step of removing an end portion of the oxide film and an end portion of the nitrogen-containing layer after removing the end portion of the single crystal semiconductor layer and before irradiating with the laser beam.

28. The method for manufacturing a semiconductor device according to claim 26, wherein the oxide film is formed by performing thermal treatment on the single crystal semiconductor substrate in an oxidative atmosphere to which halogen is added.

29. The method for manufacturing a semiconductor device according to claim 26, wherein the nitrogen-containing layer is a silicon nitride film or a silicon nitride oxide film.

30. The method for manufacturing a semiconductor device according to claim 26, wherein the single crystal semiconductor substrate is split at the fragile region by performing thermal treatment.

31. The method for manufacturing a semiconductor device according to claim 26, wherein the surface of the single crystal semiconductor layer is irradiated with the laser beam after removing the end portion of the single crystal semiconductor layer, so that the surface of the single crystal semiconductor layer is planarized.

32. The method for manufacturing a semiconductor device according to claim 26, wherein the surface of the single crystal semiconductor layer is irradiated with the laser beam after removing the end portion of the single crystal semiconductor layer, so that crystallinity of a superficial portion of the single crystal semiconductor layer is recovered.

33. The method for manufacturing a semiconductor device according to claim 26, wherein the end portion of the single crystal semiconductor layer is removed by etching.

34. The method for manufacturing a semiconductor device according to claim 26, wherein the base substrate is a glass substrate.
